(19) United States
(12) Patent Application Publication
(10) Pub. No.: US 2026/0227234 A1
(43) Pub. Date: Aug. 6, 2026

(54) PHOTODETECTION DEVICE AND ELECTRONIC DEVICE

(71) Applicants: SONY SEMICONDUCTOR SOLUTIONS CORPORATION, KANAGAWA (JP); SONY GROUP CORPORATION, TOKYO (JP)

(72) Inventors: ATSUSHI TODA, KANAGAWA (JP); HIROKI MORITA, TOKYO (JP)

(21) Appl. No.: 19/149,983

(22) PCT Filed: Jan. 17, 2024
(86) PCT No.: PCT/JP2024/001099

§ 371 Date: Jul. 22, 2025

(30) Foreign Application Priority Data
Feb. 2, 2023 (JP) 2023-014713

(51) Int. Cl. G01J 1/04; G02B 5/30

(52) U.S. Cl. CPC G01J 1/0429; G02B 5/3058

(57) ABSTRACT

There is provided an advantageous technique for suppressing reception of undesired polarized light while achieving favorable light receiving sensitivity of desired polarized light in each light receiving pixel. A photodetection device includes a polarization controller that includes a plurality of two-dimensionally arrayed microstructures and selectively transmits a plurality of types of polarized light in incident light, an additional polarizer, on which the plurality of types of polarized light from the polarization controller is made incident, that selectively transmits the plurality of types of polarized light, and a photoelectric conversion unit including a plurality of light receiving pixels that receives the plurality of types of polarized light from the additional polarizer, in which the plurality of types of polarized light transmitted through each of the polarization controller and the additional polarizer includes first polarized light, second polarized light, third polarized light, and fourth polarized light having mutually different oscillation directions.

### TECHNICAL FIELD

The present disclosure relates to a photodetection device and an electronic device.

### BACKGROUND ART

A polarization image sensor (photodetection device) including a polarizer may obtain, in addition to brightness and color information, polarization information that may not be sensed by an image sensor not including a polarizer, and a shape of a subject may also be grasped from such polarization information. Thus, the polarization image sensor may be applied to inspection and the like of an object that has been difficult to visualize and recognize in an image output from the image sensor not including a polarizer, and is expected to be used in various industrial equipment fields in the future.

Patent Document 1 discloses a solid-state imaging element including a wire grid polarizer and a photoelectric conversion element.

### CITATION LIST

### Patent Document

Patent Document 1: Japanese Patent Application Laid-Open No. 2012-80065

### SUMMARY OF THE INVENTION

### Problems to be Solved by the Invention

In recent years, polarizers including a large number of microstructures, which are also called meta-surfaces, have attracted attention. A polarization image sensor including a polarizer having a meta-surface structure tends to exhibit excellent polarized light receiving sensitivity.

For example, in the solid-state imaging element of Patent Document 1, a polarized wave transmitted through the wire grid polarizer in incident light is made incident on the photoelectric conversion element (light receiving pixel) and received. However, since the wire grid polarizer transmits only polarized light oscillating in a desired direction in the incident light and blocks polarized light oscillating in other directions, optical loss is large and low optical transmittance is exhibited. As a result, the solid-state imaging element including the wire grid polarizer tends to exhibit low sensitivity and a low extinction ratio.

Meanwhile, the polarizer having a meta-surface structure tends to exhibit excellent optical transmittance as compared with the wire grid polarizer.

However, the polarizer having a meta-surface structure may have difficulty in sufficiently suppressing emission of polarized light oscillating in a direction different from a desired direction toward a light receiving pixel intended to receive polarized light oscillating in the desired direction. As a result, in the polarization image sensor including the polarizer having a meta-surface structure, each light receiving pixel receives not only polarized light oscillating in a desired direction but also polarized light oscillating in a direction different from the desired direction, whereby it is not easy to achieve a favorable extinction ratio.

The present disclosure provides an advantageous technique for suppressing reception of undesired polarized light while achieving favorable light receiving sensitivity of desired polarized light in each light receiving pixel.

### Solutions to Problems

An aspect of the present disclosure relates to a photodetection device including a polarization controller that includes a plurality of two-dimensionally arrayed microstructures and selectively transmits a plurality of types of polarized light in incident light, an additional polarizer, on which the plurality of types of polarized light from the polarization controller is made incident, that selectively transmits the plurality of types of polarized light, and a photoelectric conversion unit including a plurality of light receiving pixels that receives the plurality of types of polarized light from the additional polarizer, in which the plurality of types of polarized light transmitted through each of the polarization controller and the additional polarizer includes first polarized light, second polarized light, third polarized light, and fourth polarized light having mutually different oscillation directions.

The polarization controller may condense the plurality of respective types of polarized light toward mutually different regions of the additional polarizer.

The additional polarizer may include a wire grid polarizer.

The additional polarizer may include a photonic crystal polarizer.

The additional polarizer may include a plurality of additional polarization pixels and an additional polarization light shielding section provided between the additional polarization pixels adjacent to each other, and each of the plurality of additional polarization pixels may selectively transmit any one of the first polarized light, the second polarized light, the third polarized light, or the fourth polarized light.

The first polarized light and the second polarized light may have the oscillation directions different from each other by 90 degrees, the third polarized light and the fourth polarized light may have the oscillation directions different from each other by 90 degrees, and the second polarized light and the third polarized light may have the oscillation directions different from each other by 45 degrees.

The polarization controller may include a first unit polarization control unit that selectively transmits the first polarized light and the second polarized light, and a second unit polarization control unit that selectively transmits the third polarized light and the fourth polarized light, the additional polarizer may include a plurality of additional polarization pixels that selectively transmits any one of the first polarized light, the second polarized light, the third polarized light, or the fourth polarized light, the first unit polarization control unit may be configured to condense the first polarized light toward the additional polarization pixel that selectively transmits the first polarized light and to condense the second polarized light toward the additional polarization pixel that selectively transmits the second polarized light, and the second unit polarization control unit may be configured to condense the third polarized light toward the additional polarization pixel that selectively transmits the third polarized light and to condense the fourth polarized light toward the additional polarization pixel that selectively transmits the fourth polarized light.

The photodetection device may include a waveguide path provided between the polarization controller and the additional polarizer, in which the waveguide path may include a first unit polarization waveguide through which the first polarized light and the second polarized light emitted from the first unit polarization control unit travel toward the additional polarizer, and a second unit polarization waveguide through which the third polarized light and the fourth polarized light emitted from the second unit polarization control unit travel toward the additional polarizer, and a polarization control light shielding section may be provided between the first unit polarization waveguide and the second unit polarization waveguide adjacent to each other.

The polarization control light shielding section may include metal.

The polarization control light shielding section may include an air layer.

The plurality of light receiving pixels may have an oblique lattice array.

The additional polarizer may include a plurality of additional polarization pixels having an oblique lattice array.

The polarization controller may include a plurality of unit polarization control units having an oblique lattice array.

Another aspect of the present disclosure relates to an electronic device including the photodetection device according to any one of the above.

### BRIEF DESCRIPTION OF DRAWINGS

FIG. 1 is a schematic diagram illustrating an exemplary configuration of an image sensor.

FIG. 2A is a partial cross-sectional view (XZ cross-sectional view) schematically illustrating an image sensor according to a first example of a first embodiment.

FIG. 2B is a partial cross-sectional view (XZ cross-sectional view) schematically illustrating the image sensor according to the first example of the first embodiment.

FIG. 3 is a plan view schematically illustrating a polarization controller (in particular, polarization control unit) according to the first example of the first embodiment.

FIG. 4 is a plan view schematically illustrating an additional polarizer (in particular, additional polarization pixel unit) according to the first example of the first embodiment.

FIG. 5 is a plan view of a polarization controller (in particular, polarization control unit) illustrating an example of a unit polarization control unit.

FIG. 6 is a plan view of an additional polarizer (in particular, additional polarization pixel unit) exemplifying a correspondence relationship between an additional polarization pixel of the additional polarizer illustrated in FIG. 4 and an oscillation direction of allocated polarized light.

FIG. 7 is a partial cross-sectional view exemplifying a traveling direction of first polarized light (oscillation direction=0 degrees) emitted from a polarization controller in the image sensor illustrated in FIG. 2A.

FIG. 8 is a partial cross-sectional view exemplifying a traveling direction of second polarized light (oscillation direction=90 degrees) emitted from the polarization controller in the image sensor illustrated in FIG. 2A.

FIG. 9 is a plan view schematically illustrating a variation of the additional polarizer.

FIG. 10 is a diagram illustrating an exemplary result of wave simulation (light receiving power distribution) based on an FDTD method by a photoelectric conversion unit (in particular, light receiving pixel unit including first to fourth light receiving pixels).

FIG. 11 is a plan view schematically illustrating a polarization controller (in particular, polarization control unit) according to a second example of the first embodiment.

FIG. 12 is a plan view schematically illustrating an additional polarizer (in particular, additional polarization pixel unit) according to the second example of the first embodiment.

FIG. 13 is a plan view schematically illustrating a polarization controller (in particular, polarization control unit) according to a third example of the first embodiment.

FIG. 14 is a plan view schematically illustrating an additional polarizer (in particular, additional polarization pixel unit) according to the third example of the first embodiment.

FIG. 15 is a plan view schematically illustrating a polarization controller (in particular, polarization control unit) according to a fourth example of the first embodiment.

FIG. 16 is a plan view schematically illustrating an additional polarizer (in particular, additional polarization pixel unit) according to the fourth example of the first embodiment.

FIG. 17 is a plan view schematically illustrating a polarization controller (in particular, polarization control unit) according to a fifth example of the first embodiment.

FIG. 18 is a plan view schematically illustrating an additional polarizer (in particular, additional polarization pixel unit) according to the fifth example of the first embodiment.

FIG. 19 is a plan view schematically illustrating a polarization controller (in particular, polarization control unit) according to a sixth example of the first embodiment.

FIG. 20 is a plan view schematically illustrating an additional polarizer (in particular, additional polarization pixel unit) according to the sixth example of the first embodiment.

FIG. 21 is a schematic plan view exemplifying a part of the photoelectric conversion unit including light receiving pixels in a square lattice array.

FIG. 22 is a schematic plan view exemplifying a part of the photoelectric conversion unit including light receiving pixels in an oblique lattice array.

FIG. 23 is a partial cross-sectional view exemplifying a traveling direction of first polarized light (oscillation direction=0 degrees) emitted from a polarization controller in an image sensor according to a first example of a second embodiment.

FIG. 24 is a partial cross-sectional view exemplifying a traveling direction of second polarized light (oscillation direction=90 degrees) emitted from the polarization controller in the image sensor according to the first example of the second embodiment.

FIG. 25 is a plan view of the polarization controller (in particular, polarization control unit) illustrating an exemplary unit polarization control unit according to the first example of the second embodiment.

FIG. 26 is a plan view schematically illustrating an additional polarizer (in particular, additional polarization pixel unit) according to the first example of the second embodiment.

FIG. 27 is a perspective view schematically illustrating the additional polarizer according to the first example of the second embodiment.

FIG. 28 is a plan view schematically illustrating a polarization controller (in particular, polarization control unit) according to a second example of the second embodiment.

FIG. 29 is a plan view schematically illustrating an additional polarizer (in particular, additional polarization pixel unit) according to the second example of the second embodiment.

FIG. 30 is a plan view schematically illustrating a polarization controller (in particular, polarization control unit) according to a third example of the second embodiment.

FIG. 31 is a plan view schematically illustrating an additional polarizer (in particular, additional polarization pixel unit) according to the third example of the second embodiment.

FIG. 32 is a plan view schematically illustrating a polarization controller (in particular, polarization control unit) according to a fourth example of the second embodiment.

FIG. 33 is a plan view schematically illustrating an additional polarizer (in particular, additional polarization pixel unit) according to the fourth example of the second embodiment.

FIG. 34 is a plan view schematically illustrating a polarization controller (in particular, polarization control unit) according to a fifth example of the second embodiment.

FIG. 35 is a plan view schematically illustrating an additional polarizer (in particular, additional polarization pixel unit) according to the fifth example of the second embodiment.

FIG. 36 is a plan view schematically illustrating a polarization controller (in particular, polarization control unit) according to a sixth example of the second embodiment.

FIG. 37 is a plan view schematically illustrating an additional polarizer (in particular, additional polarization pixel unit) according to the sixth example of the second embodiment.

FIG. 38 is a plan view of a polarization controller illustrating a first variation of the image sensor.

FIG. 39 is a cross-sectional view illustrating an exemplary YZ plane of the image sensor illustrated in FIG. 38.

FIG. 40 is a cross-sectional view illustrating an exemplary XZ plane of the image sensor illustrated in FIG. 38.

FIG. 41 is a cross-sectional view for explaining an example of a method of manufacturing an image sensor (in particular, image sensor including a wire grid additional polarizer).

FIG. 42 is a cross-sectional view for explaining an example of the method of manufacturing an image sensor (particularly, image sensor including a wire grid additional polarizer).

FIG. 43 is a cross-sectional view for explaining an example of the method of manufacturing an image sensor (in particular, image sensor including a wire grid additional polarizer).

FIG. 44 is a cross-sectional view for explaining an example of the method of manufacturing an image sensor (in particular, image sensor including a wire grid additional polarizer).

FIG. 45 is a cross-sectional view for explaining an example of the method of manufacturing an image sensor (in particular, image sensor including a wire grid additional polarizer).

FIG. 46 is a cross-sectional view for explaining an example of the method of manufacturing an image sensor (in particular, image sensor including a wire grid additional polarizer).

FIG. 47 is a cross-sectional view for explaining an example of the method of manufacturing an image sensor (in particular, image sensor including a wire grid additional polarizer).

FIG. 48 is a cross-sectional view for explaining an example of the method of manufacturing an image sensor (in particular, image sensor including a wire grid additional polarizer).

### MODE FOR CARRYING OUT THE INVENTION

Exemplary embodiments of technology of the present disclosure will be described with reference to the drawings. Hereinafter, a case where the technology of the present disclosure is applied to an image sensor (solid-state imaging element) applicable to a camera system or the like will be described. However, the application target of the technology of the present disclosure is not limited, and the technology of the present disclosure may be applied to other photodetection devices (e.g., sensors, etc.) applicable to uses other than imaging.

Note that each element in the drawings is schematically or conceptually illustrated. Thus, characteristics such as a size, a shape, and the like of each element in the drawings may be different from characteristics of an actual corresponding element. Furthermore, a size ratio between elements in the drawings may also be different from a size ratio between corresponding elements in an actual device. Furthermore, the size and shape of each element and the size ratio between elements do not necessarily coincide between the drawings, and one or a plurality of specific elements may be exaggerated in each drawing.

In the following descriptions, an X direction, a Y direction, and a Z direction are directions orthogonal to each other. For example, the X direction may correspond to the horizontal direction, the Y direction may correspond to the vertical direction (height direction), and the Z direction may correspond to the depth direction.

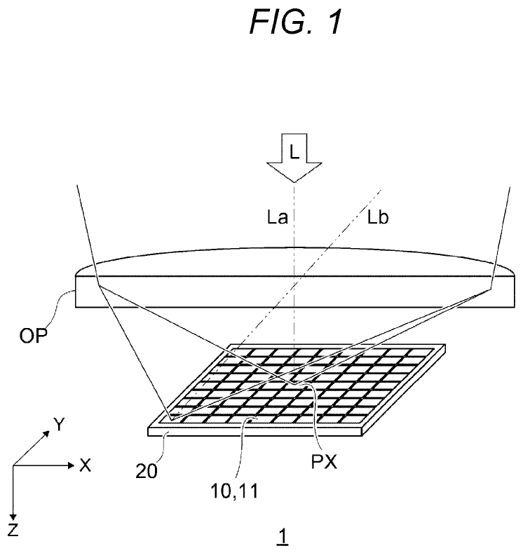

FIG. 1 is a schematic diagram illustrating an exemplary configuration of an image sensor 1. In FIG. 1, a polarization controller (polarization splitter) 10, an additional polarizer 11, and a photoelectric conversion unit 20 are illustrated in a state of being obliquely viewed, and an optical system OP is illustrated in a state of being viewed from the side.

The image sensor 1 may be typically configured by a charge coupled device (CCD) image sensor or a complementary metal oxide semiconductor (CMOS) image sensor. However, the image sensor 1 can be configured by any imaging device.

The image sensor 1 receives light from an external subject, obtains data associated with various types of information including intensity information and color information of the light, and generates an image of the subject. Polarization information of the light from the subject includes useful information that may not be obtained only from the light intensity and the color (wavelength), and may include, for example, information regarding a shape of a surface of the subject and information regarding a material of the subject. Such a polarization imaging technique using polarization information may be utilized in various fields, such as an in-vehicle camera, an Internet of Things (IoT) device, a medical device, and the like.

The image sensor 1 illustrated in FIG. 1 includes the optical system OP, the polarization controller 10, the additional polarizer 11, and the photoelectric conversion unit 20. The optical system OP includes a lens or the like that condenses incident light L from the subject. The incident light L having passed through the optical system OP includes front incident light La traveling in the optical axial direction of the principal ray and inclined incident light Lb traveling in a direction inclined with respect to the optical axis of the principal ray. In the example illustrated in FIG. 1, the optical axial direction coincides with the Z direction.

The photoelectric conversion unit 20 includes a plurality of light receiving pixels PX that receives the incident light L (in particular, plurality of types of polarized light extracted from the incident light L). In the example illustrated in FIG. 1, the plurality of light receiving pixels PX is two-dimensionally arranged in the X direction and the Y direction, and the photoelectric conversion unit 20 has a rectangular shape as a whole having sides extending in the X direction and in the Y direction. The light receiving pixel PX positioned at the central portion (image height of 0%) of the photoelectric conversion unit 20 receives the front incident light La. The light receiving pixel PX positioned away from the central portion of the photoelectric conversion unit 20 (e.g., light receiving pixel PX positioned at an end portion (e.g., image height of 100%) of the photoelectric conversion unit 20) receives the inclined incident light Lb.

Each light receiving pixel PX includes a photodiode including a silicon (Si) semiconductor material or the like. Note that, since an absorption rate (sensitivity) of the incident light may change depending on the wavelength (e.g., 940 nm) of the incident light (polarized light) in each light receiving pixel PX, a light absorption coefficient of each light receiving pixel PX is not necessarily large. Thus, as an example, a light scattering body (not illustrated) may be installed on a surface (light receiving surface) of each light receiving pixel PX to scatter the incident light by the light scattering body, whereby the optical path length of the incident light in each light receiving pixel PX may be increased to improve the sensitivity of each light receiving pixel PX.

The polarization controller 10 and the additional polarizer 11 are disposed on an optical path between the optical system OP and the photoelectric conversion unit 20, and are provided to cover the plurality of light receiving pixels PX (in particular, light receiving surface) of the photoelectric conversion unit 20. The polarization controller 10 has a meta-surface structure including a large number (a plurality) of microstructures (also referred to as “meta-atoms”). On the other hand, the additional polarizer 11 is a polarizer that does not have a meta-surface structure. As the additional polarizer 11, a polarizer having any structure (e.g., wire grid polarizer or photonic crystal polarizer to be described later) capable of extracting desired linearly polarized light from the incident light L may be used.

A portion of the polarization controller 10 and additional polarizer 11 covering the light receiving pixel PX positioned at the central portion of the photoelectric conversion unit 20 performs polarization control of the front incident light La to condense the front incident light La (in particular, polarization component) on the light receiving pixel PX positioned at the central portion of the photoelectric conversion unit 20. A portion of the polarization controller 10 and additional polarizer 11 covering the light receiving pixel PX positioned at the end portion of the photoelectric conversion unit 20 performs polarization control of the inclined incident light Lb to condense the inclined incident light Lb (in particular, polarization component) on the light receiving pixel PX positioned at the end portion of the photoelectric conversion unit 20. As described above, each portion of the polarization controller 10 and additional polarizer 11 selectively causes specific polarization components included in the incident light L incident at various angles to pass therethrough and to be condensed on the corresponding light receiving pixels PX.

The additional polarizer 11 is provided between the polarization controller 10 and the photoelectric conversion unit 20 in the optical axial direction, receives a plurality of types of polarized light from the polarization controller 10, and selectively transmits the plurality of rays of polarized light. In particular, as will be described later, the polarization controller 10 condenses each of the plurality of types of polarized light toward mutually different regions (“plurality of additional polarization pixels” to be described later) of the additional polarizer 11. The plurality of light receiving pixels PX included in the photoelectric conversion unit 20 receives the plurality of types of polarized light selectively emitted from the additional polarizer 11, The polarization controller 10 (in particular, unit polarization control unit to be described later) and the additional polarizer 11 (in particular, additional polarization pixel to be described later) are allocated to each light receiving pixel PX such that polarized light oscillating in a desired direction is selectively made incident.

In the present example, the plurality of types of polarized light transmitted through each of the polarization controller 10 and the additional polarizer 11 and received by the photoelectric conversion unit 20 includes first polarized light, second polarized light, third polarized light, and fourth polarized light having mutually different oscillation directions.

Specific oscillation directions of the first to fourth polarized light are not limited. Typically, in the incident light L immediately before entering the image sensor 1, the first polarized light and the second polarized light have mutually different oscillation directions by 90 degrees, the third polarized light and the fourth polarized light have mutually different oscillation directions by 90 degrees, and the second polarized light and the third polarized light have mutually different oscillation directions by 45 degrees. In each embodiment to be described later, the first polarized light to fourth polarized light have oscillation directions of 0 degrees, +90 degrees, −45 degrees, and +45 degrees, respectively, with respect to the propagation direction. For example, on the XY plane, the oscillation direction at 0 degrees may be a direction that coincides with the X direction, the oscillation direction at +90 degrees may be a direction that coincides with the Y direction, and the oscillation directions at −45 degrees and +45 degrees may be directions oblique to the X direction and Y direction.

The image sensor 1 (in particular, polarization controller 10 and additional polarizer 11) described above may have various configurations. Hereinafter, a typical embodiment of the image sensor 1 will be described.

### First Embodiment

An additional polarizer 11 according to the present embodiment includes a wire grid polarizer.

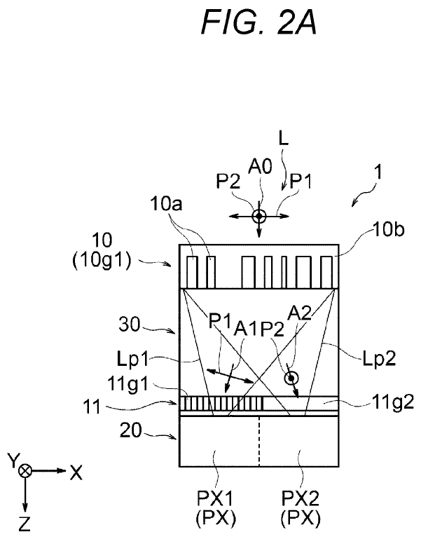

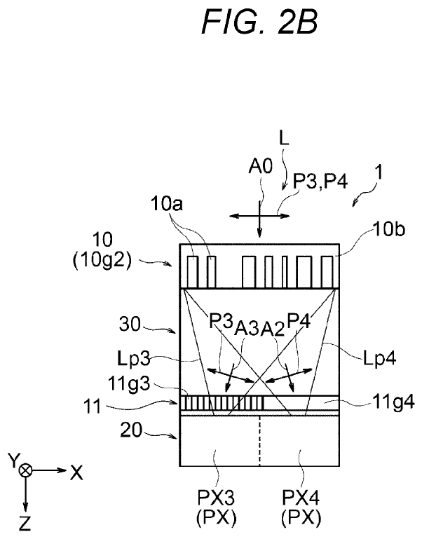

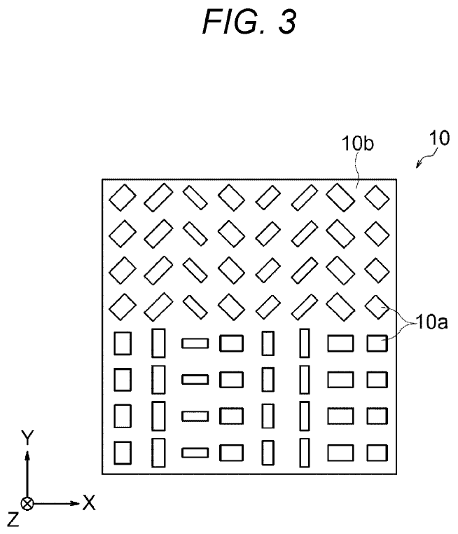

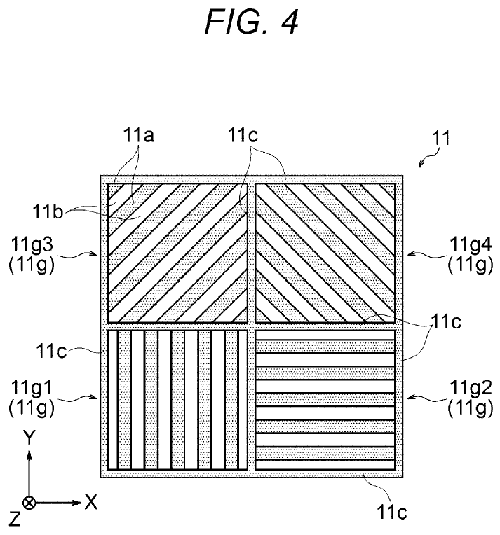

FIGS. 2A and 2B are partial cross-sectional views (XZ cross-sectional views) schematically illustrating an image sensor 1 according to a first example of a first embodiment, and illustrate a case where incident light L is perpendicularly incident on the image sensor 1 (in particular, polarization controller 10). In particular, FIG. 2A illustrates a first light receiving pixel PX1 and a second light receiving pixel PX2, and FIG. 2B illustrates a third light receiving pixel PX3 and a fourth light receiving pixel PX4. FIG. 3 is a plan view schematically illustrating the polarization controller 10 (in particular, polarization control unit) according to the first example of the first embodiment. FIG. 4 is a plan view schematically illustrating the additional polarizer 11 (in particular, additional polarization pixel unit) according to the first example of the first embodiment.

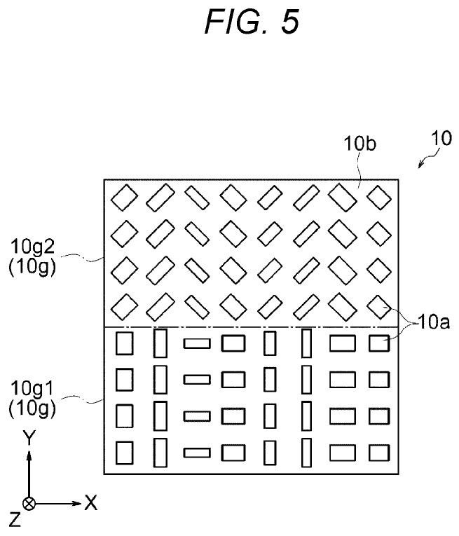

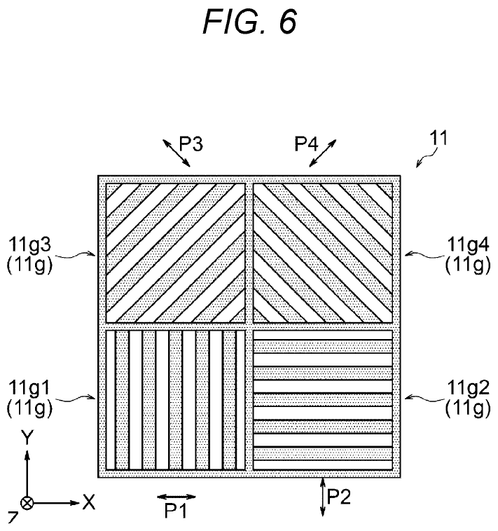

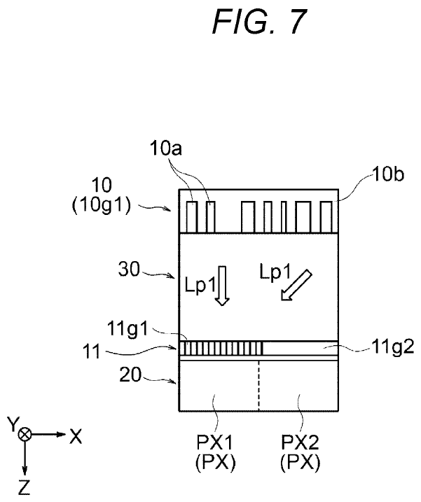

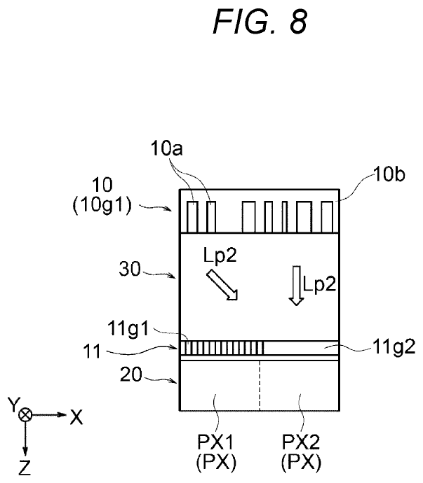

FIG. 5 is a plan view of the polarization controller 10 (in particular, polarization control unit) illustrating an example of a unit polarization control unit 10g. FIG. 6 is a plan view of the additional polarizer 11 (in particular, additional polarization pixel unit) illustrating a correspondence relationship between an additional polarization pixel 11g of the additional polarizer 11 illustrated in FIG. 4 and oscillation directions P1 to P4 of allocated polarized light. FIG. 7 is a partial cross-sectional view illustrating a traveling direction of first polarized light Lp1 (oscillation direction P1=0 degrees) emitted from the polarization controller 10 in the image sensor 1 illustrated in FIG. 2A. FIG. 8 is a partial cross-sectional view illustrating a traveling direction of second polarized light Lp2 (oscillation direction P2=90 degrees) emitted from the polarization controller 10 in the image sensor 1 illustrated in FIG. 2A.

In the examples illustrated in FIGS. 2A to 8, each of the polarization controller 10, the additional polarizer 11, and the photoelectric conversion unit 20 has a square pixel array.

That is, four light receiving pixels PX in a square lattice array in which two light receiving pixels PX are arranged in the X direction and two light receiving pixels PX are arranged in the Y direction are defined as one light receiving pixel unit, and a plurality of the light receiving pixel units is arranged in the X direction and in the Y direction. The four light receiving pixels PX (first light receiving pixel PX1 to fourth light receiving pixel PX4) included in each light receiving pixel unit are allocated to the first polarized light Lp1 to fourth polarized light Lp4, respectively (see FIGS. 2A and 2B).

Specifically, in each of the light receiving pixel units, the first light receiving pixel PX1 and the second light receiving pixel PX2 (see FIG. 2A) arranged in the X direction are light receiving pixels PX for receiving the first polarized light Lp1 (oscillation direction P1=0 degrees) and the second polarized light Lp2 (oscillation direction P2=90 degrees), respectively. In each of the light receiving pixel units, another third light receiving pixel PX3 and fourth light receiving pixel PX4 (see FIG. 2B) arranged in the X direction are light receiving pixels PX for receiving third polarized light Lp3 (oscillation direction P3=−45 degrees) and fourth polarized light Lp4 (oscillation direction P4=+45 degrees), respectively.

As described above, according to a phase of polarization information obtained by the image sensor 1 capable of separating and receiving the polarized light oscillating in the four directions, a normal vector of a subject surface may be estimated, and eventually a shape of the subject may be grasped.

The additional polarizer 11, which is a wire grid polarizer, includes a large number of wires 11a (see FIG. 4). While each of the wires 11a includes metal such as aluminum (Al), for example, it may include another material.

An inter-wire portion 11b between the adjacent wires 11a is a polarized light transmission area, which may be configured as a space (air region) or may be configured by a low refractive index material (e.g., silicon dioxide (SiO₂)).

As illustrated in FIG. 4, the additional polarizer 11 is divided into a plurality of the additional polarization pixels 11g. The plurality of additional polarization pixels 11g included in the additional polarizer 11 according to the present example has a square lattice array.

That is, four additional polarization pixels 11g in the square lattice array in which two additional polarization pixels 11g are arranged in the X direction and two additional polarization pixels 11g are arranged in the Y direction are defined as one additional polarization pixel unit, and a plurality of the additional polarization pixel units is arranged in the X direction and in the Y direction. Those four additional polarization pixels 11g included in each additional polarization pixel unit are allocated to the first polarized light Lp1 to fourth polarized light Lp4, respectively.

Specifically, as illustrated in FIG. 6, a first additional polarization pixel 11g1 and a second additional polarization pixel 11g2 arranged in the X direction in each additional polarization pixel unit selectively transmit the first polarized light Lp1 (oscillation direction P1=0 degrees) and the second polarized light (oscillation direction P2=90 degrees), respectively. Meanwhile, a third additional polarization pixel 11g3 and a fourth additional polarization pixel 11g4 arranged in the X direction in each additional polarization pixel unit selectively transmit the third polarized light Lp3 (oscillation direction P3=−45 degrees) and the fourth polarized light Lp4 (oscillation direction P4=+45 degrees), respectively.

As described above, each additional polarization pixel 11g selectively transmits any one of the first polarized light Lp1, the second polarized light Lp2, the third polarized light Lp3, and the fourth polarized light Lp4. Note that the extending direction of the wire 11a of each additional polarization pixel 11g is determined according to the oscillation direction of the allocated polarized light, and is a direction forming 90 degrees with respect to the oscillation direction of the allocated polarized light (see FIG. 6).

The additional polarizer 11 further includes a frame-shaped additional polarization light shielding section 11c (see FIG. 4) provided to surround each additional polarization pixel 11g. The additional polarization light shielding section 11c has any configuration and any composition capable of shielding transmission of light (in particular, polarized light). Thus, the additional polarization light shielding section 11c may be configured to shield light by reflecting the light, or may be configured to shield light by absorbing the light.

The additional polarization light shielding section 11c provided between the adjacent additional polarization pixels 11g in this manner may suppress leakage (crosstalk) of light (in particular, polarized light) between the adjacent additional polarization pixels 11g, which is advantageous in obtaining a higher extinction ratio.

As illustrated in FIGS. 2A and 2, the polarization controller 10 having a meta-surface structure is provided on the upstream side of the additional polarizer 11 with respect to an incident direction A0 of the incident light L. The polarization controller 10 exerts a polarization splitter function of selectively transmitting and separating the plurality of types of polarized light (first polarized light Lp1 to fourth polarized light Lp4) in the incident light L.

In the present example, a waveguide path 30 is provided between the polarization controller 10 and the photoelectric conversion unit 20 (each light receiving pixel PX). The waveguide path 30 may have any configuration, and a material that may constitute the waveguide path 30 is not limited. For example, the waveguide path 30 may include a transparent material of any of amorphous silicon, polycrystalline silicon, germanium, titanium oxide, niobium oxide, tantalum oxide, aluminum oxide, hafnium oxide, silicon nitride, silicon oxide, silicon nitride oxide, silicon carbide, silicon carbide oxide, silicon carbide nitride, or zirconium oxide.

As illustrated in FIG. 3, a plurality of meta-atoms (microstructures) 10a included in the polarization controller 10 is two-dimensionally arrayed in the X direction and in the Y direction, and is arranged in a plane substantially parallel to the light receiving surface of the light receiving pixel PX (photoelectric conversion unit 20). A refractive index of each meta-atom 10a is larger than a refractive index of a region between the meta-atoms 10a (i.e., structure peripheral portion 10b).

The meta-atom 10a may have any configuration, and a material that may constitute each meta-atom 10a is not limited. For example, each meta-atom 10a may include any of amorphous silicon (α-Si), polycrystalline silicon (Poly-Si), germanium, titanium oxide (TiO₂), niobium oxide, tantalum oxide, aluminum oxide, hafnium oxide, silicon nitride (SiN, Si₃N₄), silicon oxide, silicon nitride oxide, silicon carbide, silicon carbide oxide, silicon carbide nitride, zirconium oxide, gallium nitride (GaN), gallium arsenide (GaAs), or indium phosphide (InP).

Furthermore, the region between the meta-atoms 10a (structure peripheral portion 10b) may have any configuration, and for example, it may be provided as a space, or may be configured by a substance material such as silicon dioxide.

The meta-atom 10a and the waveguide path 30 include materials different from each other. For example, in a case where the waveguide path 30 includes a silicon oxide film or titanium oxide, the meta-atom 10a may include silicon single crystal or amorphous silicon. However, the structure peripheral portion 10b may include a material different from that of the waveguide path 30, or may include the same material as that of the waveguide path 30.

Each meta-atom 10a has a pillar shape, and is ideally configured as a rectangular parallelepiped having a rectangular cross-sectional shape and planar shape. However, in practice, if the polarization controller 10 is manufactured by processing using a photomask of lithography, corners of each meta-atom 10a may be rounded. Even if the corners of each meta-atom 10a are rounded, the polarization controller 10 may sufficiently exhibit the polarization splitter function. As described above, the shape of each meta-atom 10a is not limited, and the cross-sectional shape and planar shape of each meta-atom 10a may be any polygonal shape, elliptical shape, hollow shape, or other shapes.

The polarization controller 10 includes a plurality of types of unit polarization control units 10g that separates and emits (condenses) polarized light oscillating in mutually different directions (see FIG. 5).

Each unit polarization control unit 10g of the present example is provided in a range corresponding to the two light receiving pixels PX (i.e., region covering the two light receiving pixels PX), and selectively emits and collects two polarization components in the incident light L in mutually different directions. With this arrangement, each unit polarization control unit 10g is enabled to concentrate the polarized light incident on the range corresponding to two pixels (plurality of pixels) of the incident light L on the additional polarizer 11 (additional polarization pixel 11g) and the photoelectric conversion unit 20 (light receiving pixel PX) corresponding to one pixel (single pixel).

Specifically, the plurality of unit polarization control units 10g includes a first unit polarization control unit 10g1 and a second unit polarization control unit 10g2. That is, one first unit polarization control unit 10g1 and one second unit polarization control unit 10g2 adjacent to each other in the Y direction are defined as one polarization control unit, and a plurality of the polarization control units is arranged in the X direction and in the Y direction.

The first unit polarization control unit 10g1 is allocated to the first additional polarization pixel 11g1 and the second additional polarization pixel 11g2, and is eventually allocated to the first light receiving pixel PX1 and the second light receiving pixel PX2. The second unit polarization control unit 10g2 is allocated to the third additional polarization pixel 11g3 and the fourth additional polarization pixel 11g4, and is eventually allocated to the third light receiving pixel PX3 and the fourth light receiving pixel PX4.

The plurality of meta-atoms 10a included in each first unit polarization control unit 10g1 is linearly arrayed along each of the oscillation direction P1 (0 degrees: X direction) of the first polarized light Lp1 and the oscillation direction P2 (90 degrees: Y direction) of the second polarized light Lp2 in the incident light L. The plurality of meta-atoms 10a of each first unit polarization control unit 10g1 includes the plurality of meta-atoms 10a having mutually different sizes in the oscillation direction P1 (X direction) of the first polarized light Lp1 and the oscillation direction P2 (Y direction) of the second polarized light Lp2 in the incident light L.

The plurality of meta-atoms 10a of each second unit polarization control unit 10g2 includes the plurality of meta-atoms 10a linearly arrayed along the oscillation direction P3 (−45 degrees) of the third polarized light Lp3 and the oscillation direction P4 (+45 degrees) of the fourth polarized light Lp4 and having mutually different sizes in the oscillation directions P3 and P4.

With the plurality of meta-atoms 10a having the structure described above, each unit polarization control unit 10g selectively emits (collects) the polarization components included in the incident light L toward the additional polarizer 11 (in particular, corresponding additional polarization pixel 11g).

That is, as illustrated in FIG. 2A, the first unit polarization control unit 10g1 selectively transmits the first polarized light Lp1 and the second polarized light Lp2 in the incident light L, and emits (collects) the second polarized light Lp2 toward the second additional polarization pixel 11g2 while emitting (collecting) the first polarized light Lp1 toward the first additional polarization pixel 11g1. Note that, in FIG. 2A, the traveling direction of the first polarized light Lp1 from the first unit polarization control unit 10g1 toward the first additional polarization pixel 11g1 is represented by “A1”. In addition, the traveling direction of the second polarized light Lp2 from the first unit polarization control unit 10g1 toward the second additional polarization pixel 11g2 is represented by “A2”.

As illustrated in FIG. 7, the first polarized light Lp1 emitted from the portion covering the first light receiving pixel PX1 in the first unit polarization control unit 10g1 travels toward the first light receiving pixel PX1 along the Z direction or along an oblique direction slightly inclined with respect to the Z direction. The first polarized light Lol emitted from the portion covering the second light receiving pixel PX2 in the first unit polarization control unit 10g1 travels toward the first light receiving pixel PX1 along an oblique direction (lower left direction in FIG. 7) largely inclined with respect to the Z direction.

Meanwhile, as illustrated in FIG. 8, the second polarized light Lp2 emitted from the portion covering the second light receiving pixel PX2 in the first unit polarization control unit 10g1 travels toward the second light receiving pixel PX2 along the Z direction or along an oblique direction slightly inclined with respect to the Z direction. The second polarized light Lp2 emitted from the portion covering the first light receiving pixel PX1 in the first unit polarization control unit 10g1 travels toward the second light receiving pixel PX2 along an oblique direction (lower right direction in FIG. 8) largely inclined with respect to the Z direction.

Likewise, as illustrated in FIG. 2B, the second unit polarization control unit 10g2 selectively transmits the third polarized light Lp3 and the fourth polarized light Lp4, and emits (collects) the fourth polarized light Lp4 toward the fourth additional polarization pixel 11g4 while emitting (collecting) the third polarized light Lp3 toward the third additional polarization pixel 11g3. Note that, in FIG. 2B, the traveling direction of the third polarized light Lp3 from the second unit polarization control unit 10g2 toward the third additional polarization pixel 11g3 is represented by “A3”. In addition, the traveling direction of the fourth polarized light Lp4 from the second unit polarization control unit 10g2 toward the fourth additional polarization pixel 11g4 is represented by “A4”.

According to the image sensor 1 having the configuration described above, the polarization controller 10 is enabled to collect the corresponding desired polarized light with respect to each of the additional polarization pixels 11g of the additional polarizer 11. As a result, incidence of undesired polarized light on each of the additional polarization pixels 11g may be suppressed, and a loss of light in the additional polarizer 11 may be effectively reduced.

Furthermore, each of the additional polarization pixels 11g effectively suppresses transmission of undesired polarized light while allowing transmission of desired polarized light.

Therefore, the image sensor 1 according to the present example is enabled to suppress reception of undesired polarized light while securing favorable light receiving sensitivity of desired polarized light in each light receiving pixel PX, which is advantageous for achieving a higher extinction ratio.

Note that the image sensor 1 may appropriately employ a configuration different from the configuration illustrated in FIGS. 2A to 8 described above.

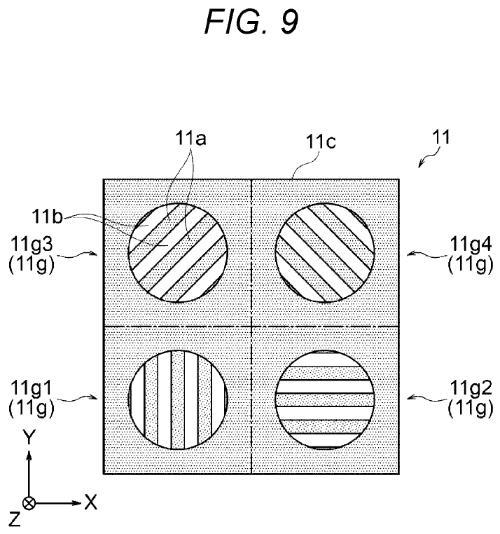

FIG. 9 is a plan view schematically illustrating a variation of the additional polarizer 11.

From the viewpoint of more effectively suppressing the crosstalk, it is preferable that the additional polarization light shielding section 11c of the additional polarizer 11 is provided so that the distance between substantial translucent areas (inter-wire portions 11b) of the adjacent additional polarization pixels 11g increases. In the example illustrated in FIG. 9, the additional polarization light shielding section 11c is provided such that the substantial translucent area (inter-wire portion 11b) of each additional polarization pixel 11g has a circular planar shape at the center of each pixel.

As described above, the additional polarization light shielding section 11c is provided as a diaphragm that limits the translucent area through which the light (in particular, polarized light) in each additional polarization pixel 11g may be transmitted, whereby the incidence of undesired polarized light on each light receiving pixel PX may be suppressed, and eventually the extinction ratio may be improved.

Next, an exemplary result of wave simulation of a finite-difference time-domain (FDTD) method performed using the image sensor 1 having the above-described structure illustrated in FIGS. 1 to 8 will be described.

### [First Simulation Result]

In the present simulation, the incident light L (in particular, first polarized light Lp1 (i.e., incident light L including only the first polarized light Lp1 without including the second polarized light Lp2 to fourth polarized light Lp4)) having a wavelength of 940 nm was perpendicularly made incident on the image sensor 1 having the structure illustrated in FIGS. 1 to 8.

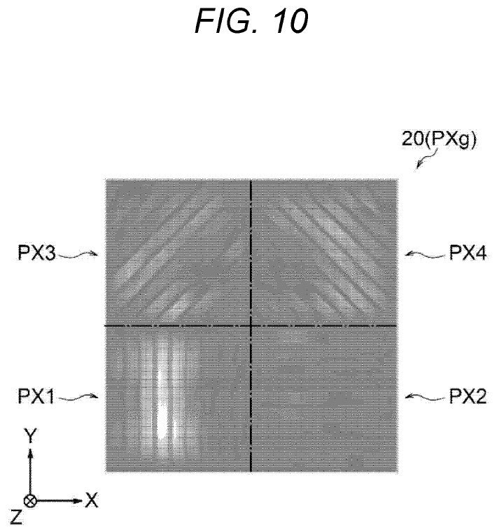

FIG. 10 is a diagram illustrating an exemplary result of the wave simulation (light receiving power distribution) based on the FDTD method by the photoelectric conversion unit 20 (in particular, light receiving pixel unit PXg including the first light receiving pixel PX1 to fourth light receiving pixel PX4). In the light receiving pixel unit PXg illustrated in FIG. 10, a portion represented by a color closer to white indicates that the first polarized light Lp1 is received more strongly, and a portion represented by a color closer to black indicates that the light receiving intensity of the first polarized light Lp1 is weaker.

In the exemplary result illustrated in FIG. 10, the first light receiving pixel PX1 receives the first polarized light Lp1 relatively strongly, and the light receiving intensity of the first light receiving pixel PX1 by another light receiving pixel PX (particularly the second light receiving pixel PX2) is relatively weak.

As described above, the first polarized light Lp1 is condensed on the first additional polarization pixel 11g1 by the polarization controller 10 (in particular, first unit polarization control unit 10g1), transmitted through the first additional polarization pixel 11g1, and guided to be intensively made incident on the first light receiving pixel PX1. That is, the first polarized light Lp1 is guided by the polarization controller 10 not to be made incident on the additional polarization pixel 11g other than the first additional polarization pixel 11g1, and eventually not to be essentially made incident on the light receiving pixel PX other than the first light receiving pixel PX1.

The simulation result illustrated in FIG. 10 also matches such structural characteristics of the image sensor 1 in FIGS. 1 to 8, and confirms that the image sensor 1 illustrated in FIGS. 1 to 8 is advantageous in selectively and intensively receiving the first polarized light Lp1 with the first light receiving pixel PX1.

Note that, while FIG. 10 illustrates the simulation result regarding the first polarized light Lp1, similar simulation results were obtained for other types of polarized light (second polarized light Lp2 to fourth polarized light Lp4). That is, the simulation results confirm that the image sensor 1 illustrated in FIGS. 1 to 8 is advantageous in selectively and intensively receiving the second polarized light Lp2 to fourth polarized light Lp4 with the second light receiving pixel PX2 to fourth light receiving pixel PX4, respectively.

### [Second Simulation Result]

The inventors of the present case also conducted a simulation based on presence or absence of the polarization controller 10 and the additional polarizer 11. That is, a simulation based on “the image sensor 1 including the polarization controller 10 and the additional polarizer 11” and “the image sensor 1 including only one of the polarization controller 10 or the additional polarizer 11 (not including the other)” was also conducted.

Here, the “image sensor 1 including the polarization controller 10 and the additional polarizer 11” has the above-described structure illustrated in FIGS. 1 to 8. On the other hand, the “image sensor 1 including only one of the polarization controller 10 or the additional polarizer 11” has a structure in which the polarization controller 10 or the additional polarizer 11 is removed from the above-described structure illustrated in FIGS. 1 to 8.

Configurations other than the polarization controller 10 and the additional polarizer 11 were made common among the simulated image sensors 1.

A table 1 set out below illustrates an exemplary result of the simulation conducted on the basis of “the image sensor 1 including the polarization controller 10 and the additional polarizer 11” and “the image sensor 1 including only one of the polarization controller 10 or the additional polarizer 11”.

TABLE 1

| | | | Light | |
|---|---|---|---|---|
| | | Light | receiving | |
| | | receiving | power of | |
| | | power of | second | |
| | | first light | light | |
| | | receiving | receiving | Extinction |
| No. | Image sensor structure | pixel | pixel | ratio |
| 1 | Polarization controller: | 0.59640 | 0.19060 | 3.1284 |
| | provided | | | |
| | Additional polarizer: not | | | |
| | provided | | | |
| 2 | Polarization controller: not | 0.11625 | 0.0022389 | 51.921 |
| | provided | | | |
| | Additional polarizer: | | | |
| | provided | | | |
| 3 | Polarization controller: | 0.30311 | 0.00047402 | 639.45 |
| | provided | | | |
| | Additional polarizer: | | | |
| | provided | | | |

In the present simulation, the incident light L (in particular, first polarized light Lp1 (i.e., incident light L including only the first polarized light Lp1 without including the second polarized light Lp2 to fourth polarized light Lp4)) having the same light intensity and a wavelength of 940 nm was perpendicularly made incident on the image sensor 1.

In the table 1 set out above, “light receiving power of the first light receiving pixel” and “light receiving power of the second light receiving pixel” are numerical values indicating the light receiving intensity of the first polarized light Lp1 by the first light receiving pixel PX1 and the second light receiving pixel PX2, respectively. The larger the numerical value of the “light receiving power of the first light receiving pixel”, the higher the light receiving sensitivity of the desired polarized light in each light receiving pixel PX (in the present example, light receiving sensitivity of the first polarized light Lp1 in the first light receiving pixel PX1), which is normally preferable. On the other hand, the larger the numerical value of the “light receiving power of the second light receiving pixel”, the higher the light receiving sensitivity of the undesired polarized light in each light receiving pixel PX (in the present example, light receiving sensitivity of the first polarized light Lp1 in the second light receiving pixel PX2), which is not normally preferable.

Furthermore, in the table 1 set out above, an “extinction ratio” indicates a ratio between the “light receiving power of the first light receiving pixel” and the “light receiving power of the second light receiving pixel” (extinction ratio=light receiving power of the first light receiving pixel/light receiving power of the second light receiving pixel). The light receiving sensitivity of the desired polarized light is higher and the light receiving sensitivity of the undesired polarized light is lower in each light receiving pixel PX as the value of the extinction ratio increases.

According to the result of the table 1, in a case where the polarization controller 10 is provided and the additional polarizer 11 is not provided (see number “1”), while the light receiving power of the first light receiving pixel PX1 is larger with respect to the first polarized light Lp1, the light receiving power of the second light receiving pixel PX2 is also larger. As a result, it is understood that a relatively high extinction ratio may not be obtained in the case where the polarization controller 10 is provided and the additional polarizer 11 is not provided.

In addition, according to the result of the table 1, in a case where the polarization controller 10 is not provided and the additional polarizer 11 is provided (see number “2”), the light receiving power of the first light receiving pixel PX1 is relatively small. Thus, it is understood that the intensity of the first polarized light Lp1 that passes through the additional polarizer 11 and reaches the first light receiving pixel PX1 is inherently low, resulting in low sensitivity of the image sensor 1. As a result, it is understood that a relatively high extinction ratio may not be obtained also in the case where the polarization controller 10 is not provided and the additional polarizer 11 is provided.

Meanwhile, according to the result of the table 1, in a case where the polarization controller 10 and the additional polarizer 11 are provided (see number “3”), both the securing of the light receiving power of the first light receiving pixel PX1 and the reduction of the light receiving power of the second light receiving pixel PX2 with respect to the first polarized light Lp1 are achieved in a well-balanced manner.

For example, compared with the case where only the additional polarizer 11 is provided (number “2”), in the case where the polarization controller 10 and the additional polarizer 11 are provided (number “3”), the light receiving power of the first light receiving pixel PX1 with respect to the first polarized light Lp1 was increased by about three times. Furthermore, compared with the case where only the additional polarizer 11 is provided (number “2”), in the case where the polarization controller 10 and the additional polarizer 11 are provided (number “3”), the light receiving power of the second light receiving pixel PX2 with respect to the first polarized light Lp1 was reduced to about ⅕.

As a result, compared with the case where only the additional polarizer 11 is provided (number “2”), in the case where the polarization controller 10 and the additional polarizer 11 are provided (number “3”), the extinction ratio was increased by about 12 times. Furthermore, compared with the case where only the polarization controller 10 is provided (number “1”), in the case where the polarization controller 10 and the additional polarizer 11 are provided (number “3”), the extinction ratio was increased by about 204 times.

Also from the result of the table 1 described above, it is understood that, with the polarization controller 10 and the additional polarizer 11 being provided, the image sensor 1 is enabled to achieve the “high sensitivity to the desired polarized light” and the “low sensitivity to the undesired polarized light” with respect to each light receiving pixel PX, and to obtain an extraordinarily high extinction ratio. Therefore, according to the output result of the image sensor 1 according to the present embodiment, more accurate phase estimation of polarized light may be obtained, and eventually, the normal vector of the subject surface may be estimated and the shape may be grasped more accurately.

Next, another example of the first embodiment will be described.

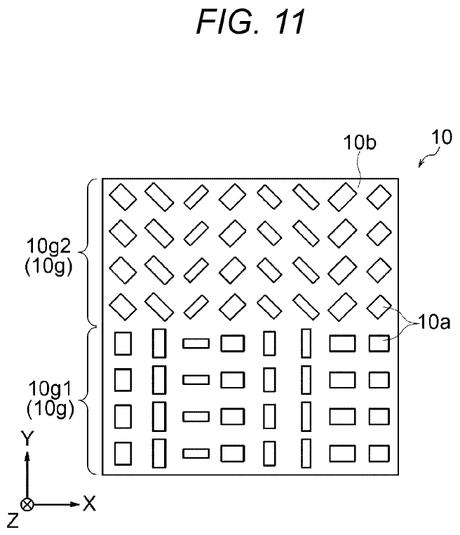

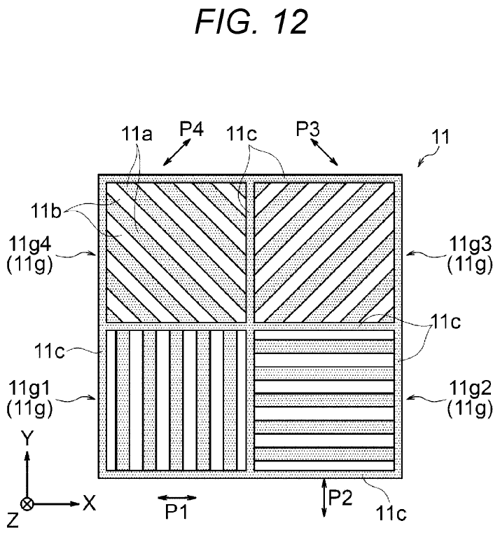

FIG. 11 is a plan view schematically illustrating the polarization controller 10 (in particular, polarization control unit) according to a second example of the first embodiment. FIG. 12 is a plan view schematically illustrating the additional polarizer 11 (in particular, additional polarization pixel unit) according to the second example of the first embodiment.

In the second example, the arrangement of the third light receiving pixel PX3 and the fourth light receiving pixel PX4 in each light receiving pixel unit PXg of the photoelectric conversion unit 20 is changed from the arrangement according to the first example described above (see FIG. 10). That is, the fourth light receiving pixel PX4 is arranged to be adjacent to the first light receiving pixel PX1 in the Y direction, and the third light receiving pixel PX3 is arranged to be adjacent to the second light receiving pixel PX2 in the Y direction.

Thus, in the second example, as illustrated in FIG. 12, the arrangement of the third additional polarization pixel 11g3 and the fourth additional polarization pixel 11g4 in each additional polarization pixel unit of the additional polarizer 11 is changed from the arrangement according to the first example (see FIG. 4). That is, the fourth additional polarization pixel 11g4 is arranged to be adjacent to the first additional polarization pixel 11g1 in the Y direction, and the third additional polarization pixel 11g3 is arranged to be adjacent to the second additional polarization pixel 11g2 in the Y direction.

Note that, in the second example, the arrangement of the first light receiving pixel PX1 and the second light receiving pixel PX2 in each light receiving pixel unit PXg is changed from the arrangement according to the first example described above (see FIG. 10). Thus, in the second example, as illustrated in FIG. 12, the arrangement of the first additional polarization pixel 11g1 and the second additional polarization pixel 11g2 in each additional polarization pixel unit of the additional polarizer 11 is the same as the arrangement according to the first example (see FIG. 4).

The polarization controller 10 has a meta-surface structure (plurality of meta-atoms 10a and structure peripheral portion 10b) that selectively emits the first polarized light Lp1 to fourth polarized light Lp4 toward the first additional polarization pixel 11g1 to fourth additional polarization pixel 11g4, respectively.

Thus, also in the present example, the first polarized light Lp1 to fourth polarized light Lp4 are condensed on the first additional polarization pixel 11g1 to fourth additional polarization pixel 11g4 of the additional polarizer 11, respectively, by the polarization controller 10, and selectively transmit the first additional polarization pixel 11g1 to fourth additional polarization pixel 11g4, respectively. As a result, the first polarized light Lp1 to fourth polarized light Lp4 are selectively received by the first light receiving pixel PX1 to fourth light receiving pixel PX4 of the photoelectric conversion unit 20, respectively.

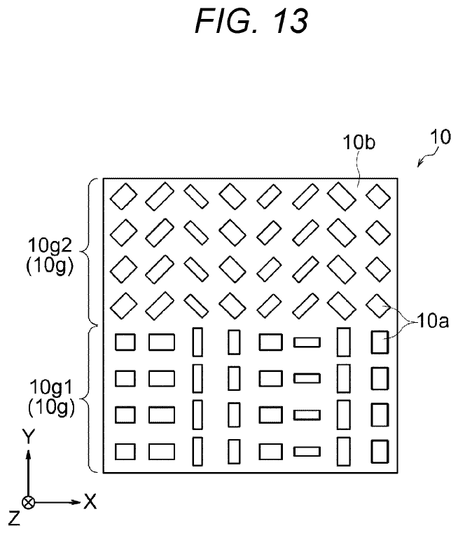

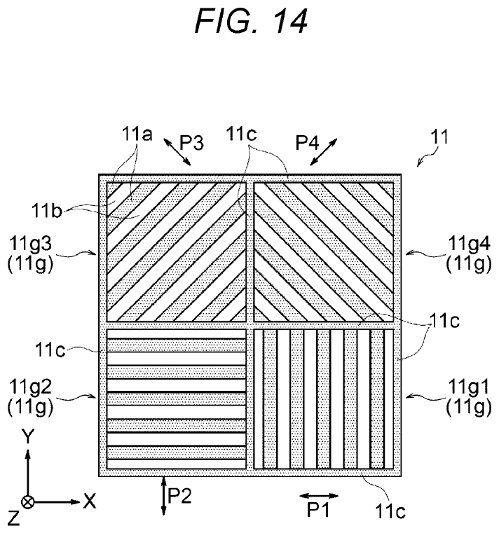

FIG. 13 is a plan view schematically illustrating the polarization controller 10 (in particular, polarization control unit) according to a third example of the first embodiment. FIG. 14 is a plan view schematically illustrating the additional polarizer 11 (in particular, additional polarization pixel unit) according to the third example of the first embodiment.

In the third example, the arrangement of the first light receiving pixel PX1 and the second light receiving pixel PX2 in each light receiving pixel unit PXg of the photoelectric conversion unit 20 is changed from the arrangement according to the first example described above (see FIG. 10). That is, the fourth light receiving pixel PX4 is arranged to be adjacent to the first light receiving pixel PX1 in the Y direction, and the third light receiving pixel PX3 is arranged to be adjacent to the second light receiving pixel PX2 in the Y direction.

Thus, in the third example, as illustrated in FIG. 14, the arrangement of the first additional polarization pixel 11g1 and the second additional polarization pixel 11g2 in each additional polarization pixel unit of the additional polarizer 11 is changed from the arrangement according to the first example (see FIG. 4). That is, the fourth additional polarization pixel 11g4 is arranged to be adjacent to the first additional polarization pixel 11g1 in the Y direction, and the third additional polarization pixel 11g3 is arranged to be adjacent to the second additional polarization pixel 11g2 in the Y direction.

Note that, in the third example, the arrangement of the third light receiving pixel PX3 and the fourth light receiving pixel PX4 in each light receiving pixel unit PXg is the same as the arrangement according to the first example described above. In addition, in the third example, the arrangement of the third additional polarization pixel 11g3 and the fourth additional polarization pixel 11g4 in each additional polarization pixel unit is the same as the arrangement according to the first example described above.

The polarization controller 10 has a meta-surface structure (plurality of meta-atoms 10a and structure peripheral portion 10b) that selectively emits the first polarized light Lp1 to fourth polarized light Lp4 toward the first additional polarization pixel 11g1 to fourth additional polarization pixel 11g4, respectively.

Thus, also in the present example, the first polarized light Lp1 to fourth polarized light Lp4 are condensed on the first additional polarization pixel 11g1 to fourth additional polarization pixel 11g4 of the additional polarizer 11, respectively, by the polarization controller 10, and selectively transmit the first additional polarization pixel 11g1 to fourth additional polarization pixel 11g4, respectively. As a result, the first polarized light Lp1 to fourth polarized light Lp4 are selectively received by the first light receiving pixel PX1 to fourth light receiving pixel PX4 of the photoelectric conversion unit 20, respectively.

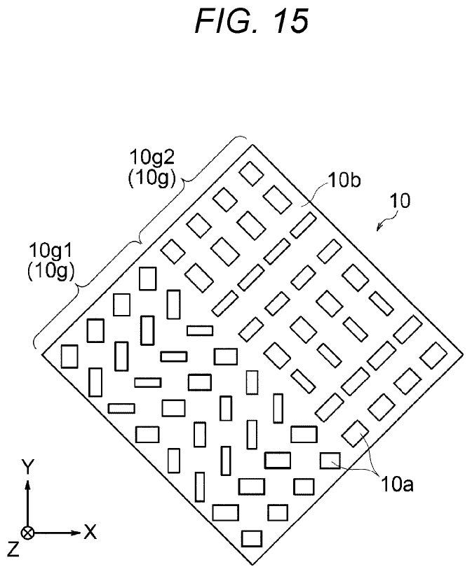

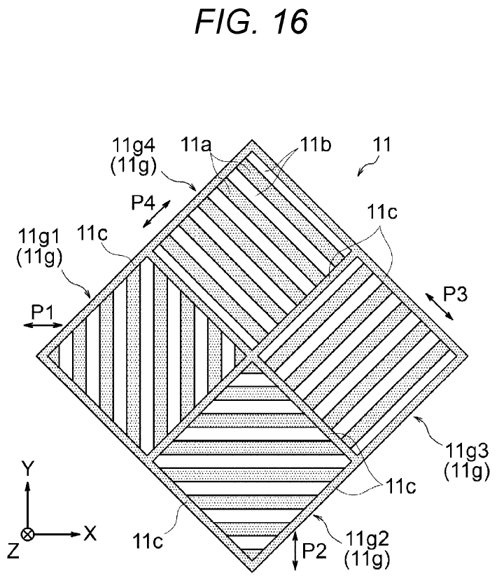

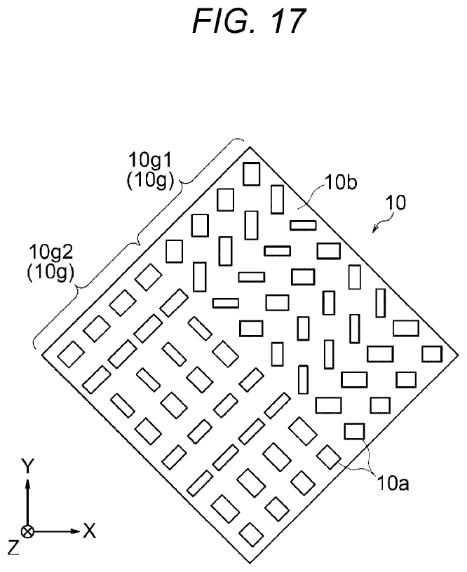

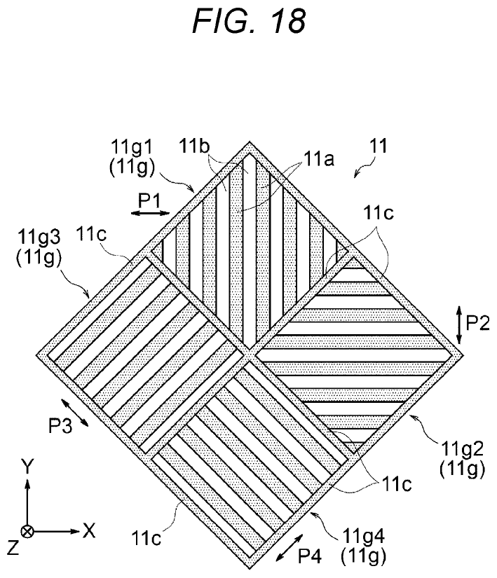

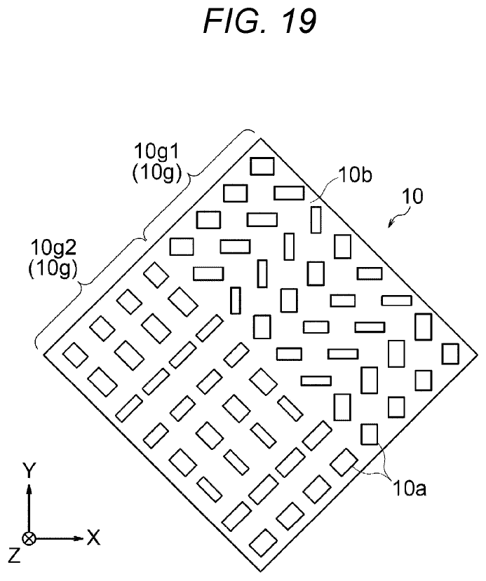

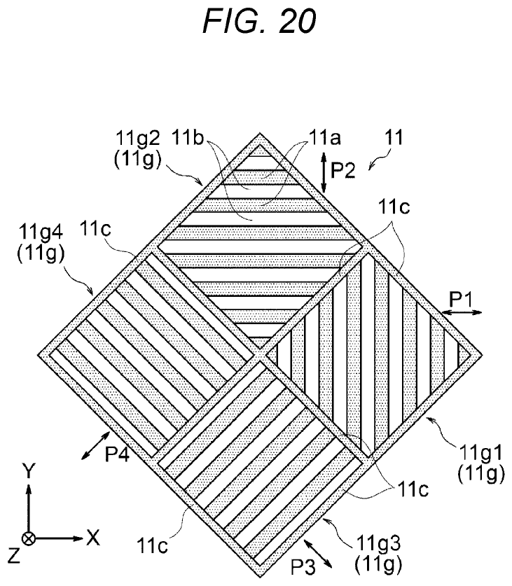

FIG. 15 is a plan view schematically illustrating the polarization controller 10 (in particular, polarization control unit) according to a fourth example of the first embodiment. FIG. 16 is a plan view schematically illustrating the additional polarizer 11 (in particular, additional polarization pixel unit) according to the fourth example of the first embodiment. FIG. 17 is a plan view schematically illustrating the polarization controller 10 (in particular, polarization control unit) according to a fifth example of the first embodiment. FIG. 18 is a plan view schematically illustrating the additional polarizer 11 (in particular, additional polarization pixel unit) according to the fifth example of the first embodiment. FIG. 19 is a plan view schematically illustrating the polarization controller 10 (in particular, polarization control unit) according to a sixth example of the first embodiment. FIG. 20 is a plan view schematically illustrating the additional polarizer 11 (in particular, additional polarization pixel unit) according to the sixth example of the first embodiment.

In the fourth to sixth examples illustrated in FIGS. 15 to 20, the plurality of light receiving pixels PX has an oblique lattice array, and is two-dimensionally arranged in a direction inclined with respect to each of the X direction and the Y direction (e.g., direction inclined by 45 degrees with respect to each of the X direction and the Y direction). In addition, in the fourth to sixth examples, the plurality of unit polarization control units 10g included in the polarization controller 10 has an oblique lattice array (see FIGS. 15, 17, and 19). Furthermore, in the fourth to sixth examples, the plurality of additional polarization pixels 11g included in the additional polarizer 11 has an oblique lattice array (see FIGS. 16, 18, and 20).

Then, in the fourth to sixth examples, the plurality of light receiving pixel units, the plurality of additional polarizing pixel units, and the plurality of polarization control units are two-dimensionally arrayed in a direction oblique to each of the X direction and the Y direction.

However, in the fourth to sixth examples, the relative arrangement between the first light receiving pixel PX1 to fourth light receiving pixel PX4, which receive the first polarized light Lp1 to fourth polarized light Lp4, respectively, is different.

That is, in the fourth example, in each light receiving pixel unit, the first light receiving pixel PX1 and the third light receiving pixel PX3 are arranged in the X direction, and the second light receiving pixel PX2 and the fourth light receiving pixel PX4 are arranged in the Y direction. Thus, as illustrated in FIG. 16, in each additional polarization unit, the first additional polarization pixel 11g1 and the third additional polarization pixel 11g3 are arranged in the X direction, and the second additional polarization pixel 11g2 and the fourth additional polarization pixel 11g4 are arranged in the Y direction.

In the fifth example, in each light receiving pixel unit, the third light receiving pixel PX3 and the second light receiving pixel PX2 are arranged in the X direction, and the fourth light receiving pixel PX4 and the first light receiving pixel PX1 are arranged in the Y direction. Thus, as illustrated in FIG. 18, in each additional polarization unit, the third additional polarization pixel 11g3 and the second additional polarization pixel 11g2 are arranged in the X direction, and the fourth additional polarization pixel 11g4 and the first additional polarization pixel 11g1 are arranged in the Y direction.

In the sixth example, in each light receiving pixel unit, the fourth light receiving pixel PX4 and the first light receiving pixel PX1 are arranged in the X direction, and the third light receiving pixel PX3 and the second light receiving pixel PX2 are arranged in the Y direction. Thus, as illustrated in FIG. 20, in each additional polarization unit, the fourth additional polarization pixel 11g4 and the first additional polarization pixel 11g1 are arranged in the X direction, and the third additional polarization pixel 11g3 and the second additional polarization pixel 11g2 are arranged in the Y direction.

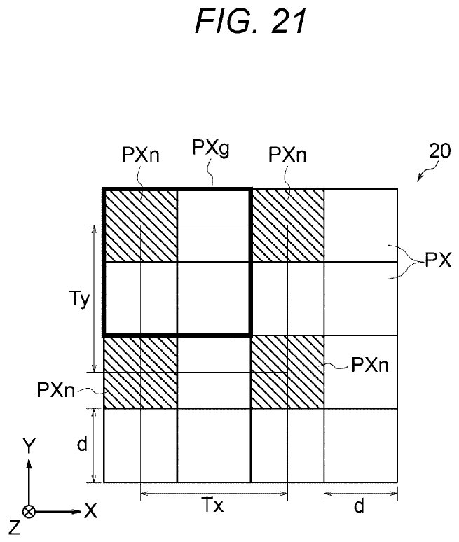

FIG. 21 is a schematic plan view illustrating a part of the photoelectric conversion unit 20 including the light receiving pixels PX in the square lattice array. FIG. 22 is a schematic plan view illustrating a part of the photoelectric conversion unit 20 including the light receiving pixels PX in the oblique lattice array.

In FIGS. 21 and 22, a specific light receiving pixel (one light receiving pixel PX among the first light receiving pixel PX1 to fourth light receiving pixel PX4) for receiving specific polarized light (one polarized light among the first polarized light Lp1 to fourth polarized light Lp4) is represented by “PXn”. Furthermore, in FIGS. 21 and 22, a periodic distance in the X direction (X-direction periodic distance) between the specific light receiving pixels PXn is represented by “Tx”, and a periodic distance in the Y direction (Y-direction periodic distance) between the specific light receiving pixels PXn is represented by “Ty”.

As illustrated in FIG. 21, the X-direction periodic distance Tx and the Y-direction periodic distance Ty of the light receiving pixels PX in the square lattice array are twice the size of each light receiving pixel PX (Tx=Ty=2d) in the X direction and the Y direction (light receiving pixel size d).

Meanwhile, the X-direction periodic distance Tx and the Y-direction periodic distance Ty of the light receiving pixels PX in the oblique lattice array illustrated in FIG. 22 are √2 times the light receiving pixel size d (Tx=Ty=√2d).

Thus, the light receiving pixel PX in the oblique lattice array (FIG. 22) has a smaller X-direction periodic distance Tx and Y-direction periodic distance Ty (specifically, 1/√2 times the X-direction periodic distance Tx and Y-direction periodic distance Ty) than those of the light receiving pixel PX in the square lattice array (FIG. 21).

As described above, the light receiving pixel PX (FIG. 22) in the oblique lattice array substantially has finer (higher) resolution in the X direction (corresponding to the horizontal direction) and in the Y direction (corresponding to the vertical direction) than that of the light receiving pixel PX (FIG. 21) in the square lattice array. Therefore, the image sensors 1 according to the fourth to sixth examples based on the oblique lattice array described above are advantageous in obtaining an image with higher resolution in the horizontal direction and in the vertical direction as compared with the image sensors 1 according to the first to third examples based on the square lattice array described above.

Considering visual characteristics that human eyes are more sensitive to changes in the horizontal direction and in the vertical direction than in the oblique direction, it is preferable that the resolution of the image in the horizontal direction (X direction) and in the vertical direction (Y direction) is higher. Therefore, the image sensors 1 according to the fourth to sixth examples based on the oblique lattice array are advantageous in obtaining an image with resolution preferable in terms of the human visual characteristics.

In particular, the polarization controller 10 having the meta-surface structure collects light from a wide range, and emits a plurality of types of polarized light (four types of polarized light) toward mutually different additional polarization pixels 11g and mutually different light receiving pixels PX. In such an image sensor 1 including the polarization controller 10 and the additional polarizer 11, while the resolution is likely to deteriorate in principle, the deterioration of the resolution may be effectively suppressed by the oblique lattice array described above being adopted.

Note that the image sensors 1 according to the fourth to sixth examples based on the oblique lattice array described above may employ configurations similar to those of the image sensors 1 according to the first to third examples based on the square lattice array described above. For example, in a similar manner to the first example, as illustrated in FIG. 9 described above, the additional polarizers 11 according to the second to sixth examples may include the additional polarization light shielding section 11c that limits the substantial translucent areas of each additional polarization pixel 11g and increases a distance between the translucent areas of the adjacent additional polarization pixels 11g.

### Second Embodiment

In the present embodiment, elements same as or corresponding to those in the first embodiment described above will be denoted by the same reference signs, and detailed descriptions thereof will be omitted.

An additional polarizer 11 according to the present embodiment includes a photonic crystal polarizer.

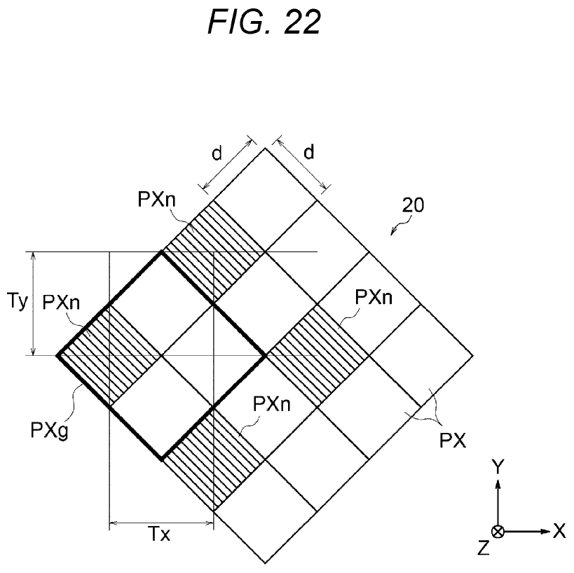

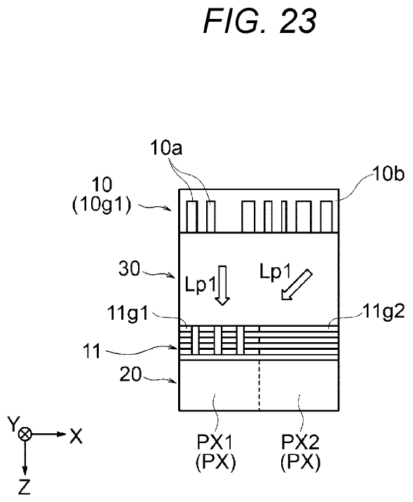

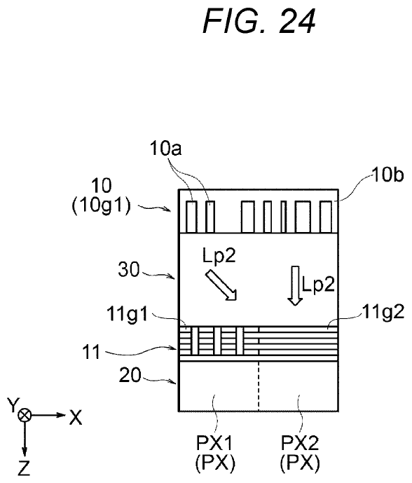

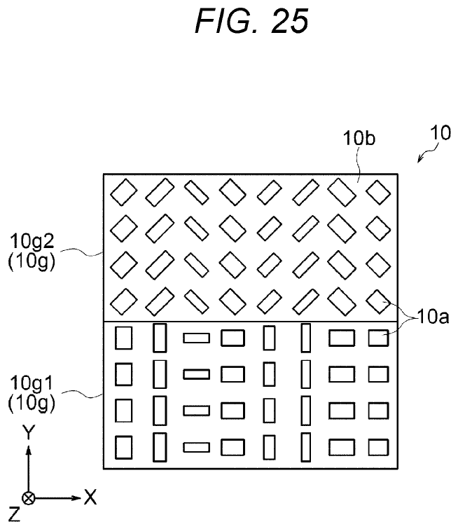

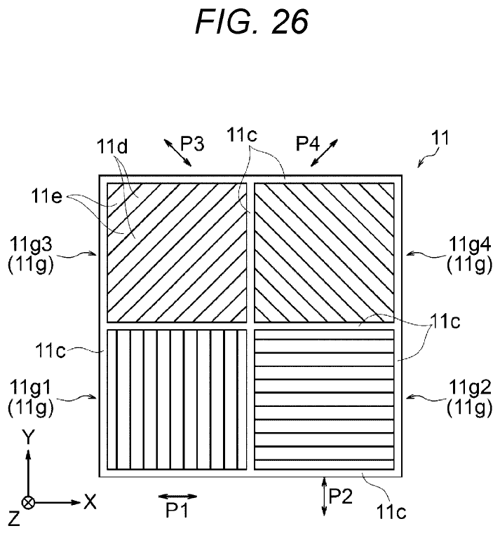

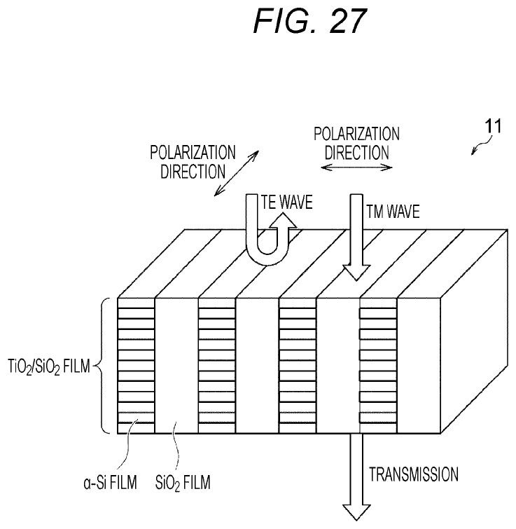

FIG. 23 is a partial cross-sectional view illustrating a traveling direction of first polarized light (oscillation direction P1=0 degrees) emitted from a polarization controller 10 in an image sensor 1 according to a first example of the second embodiment. FIG. 24 is a partial cross-sectional view illustrating a traveling direction of second polarized light (oscillation direction P2=90 degrees) emitted from the polarization controller 10 in the image sensor 1 according to the first example of the second embodiment. FIG. 25 is a plan view of the polarization controller 10 (in particular, polarization control unit) illustrating an exemplary unit polarization control unit 10g according to the first example of the second embodiment. FIG. 26 is a plan view schematically illustrating the additional polarizer 11 (in particular, additional polarization pixel unit) according to the first example of the second embodiment. FIG. 27 is a perspective view schematically illustrating the additional polarizer 11 according to the first example of the second embodiment.

The photonic crystal polarizer included in the additional polarizer 11 has a characteristic of selectively transmitting and emitting polarized light according to the oscillation direction in a similar manner to the wire grid polarizer described above.

The photonic crystal polarizer has a photonic crystal structure in which materials having different refractive indexes are periodically arranged, and the additional polarizer 11 according to the present example includes a low refractive index material 11d and a high refractive index material 11e that are periodically arranged. The additional polarizer 11 has, for example, a multilayer film of an amorphous silicon (α-Si) layer having a high refractive index and a silicon oxide (SiO₂) layer having a low refractive index, whereby a one-dimensional photonic band gap may be formed.

Note that the photonic crystal additional polarizer 11 may be configured by a combination of the low refractive index material 11d and the high refractive index material 11e based on other compositions. For example, the high refractive index material 11e may be titanium oxide (TiO₂), silicon nitride (Si₃N₄), tantalum oxide (Ta₂O₅), or hafnium oxide (HfO₂).

Grooves with a periodic pitch are formed in the multilayer film of the additional polarizer 11 by a manufacturing method such as dry etching processing, and a material (silicon dioxide in the present example) having a different refractive index is embedded in the grooves. With this arrangement, as illustrated in FIG. 27, the additional polarizer 11 is enabled to transmit polarized light (TM wave) oscillating in a direction forming 90 degrees with respect to the extending direction of the grooves while reflecting polarized light (TE wave) oscillating in the same direction as the extending direction of the grooves. As described above, the photonic crystal polarizer may selectively transmit polarized light oscillating in a specific direction.

As illustrated in FIG. 26, an additional polarization unit of the additional polarizer 11 according to the present example includes a first additional polarization pixel 11g1 to fourth additional polarization pixel 11g4 in a square pixel array having a photonic crystal structure that selectively transmit first polarized light Lp1 to fourth polarized light Lp4, respectively. Furthermore, as an additional polarization light shielding section 11c provided between the adjacent additional polarization pixels 11g, a frame member (e.g., light shielding film including tungsten (W)) having an excellent light shielding property is provided.

Also in the present example, in a similar manner to the first example of the first embodiment described above, the first polarized light Lp1 to fourth polarized light Lp4 are condensed on the first additional polarization pixel 11g1 to fourth additional polarization pixel 11g4 of the additional polarizer 11, respectively, by the polarization controller 10. Then, the first polarized light Lp1 to fourth polarized light Lp4 are selectively transmitted through the first additional polarization pixel 11g1 to fourth additional polarization pixel 11g4, respectively, and are selectively received by a first light receiving pixel PX1 to fourth light receiving pixel PX4 of a photoelectric conversion unit 20, respectively.

Next, another example of the second embodiment will be described.

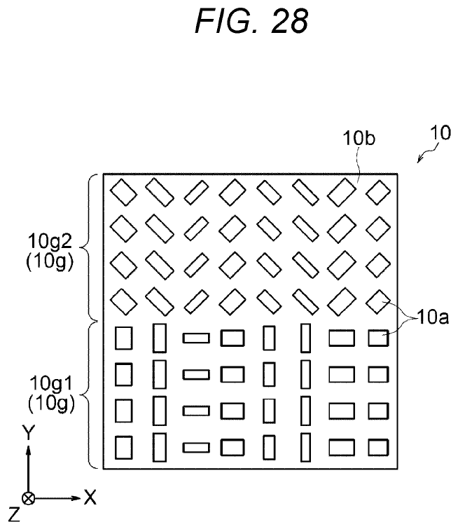

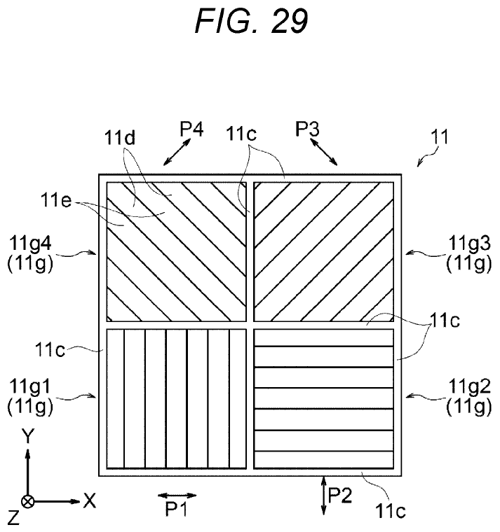

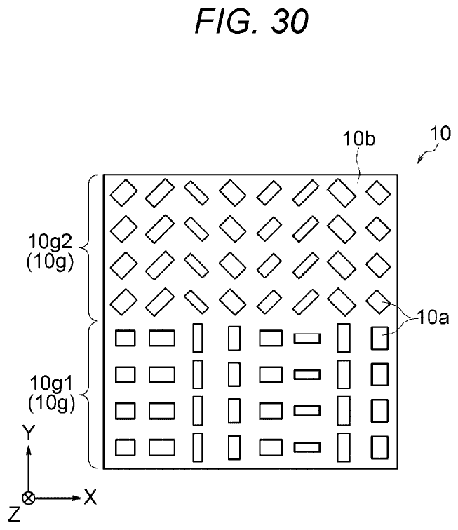

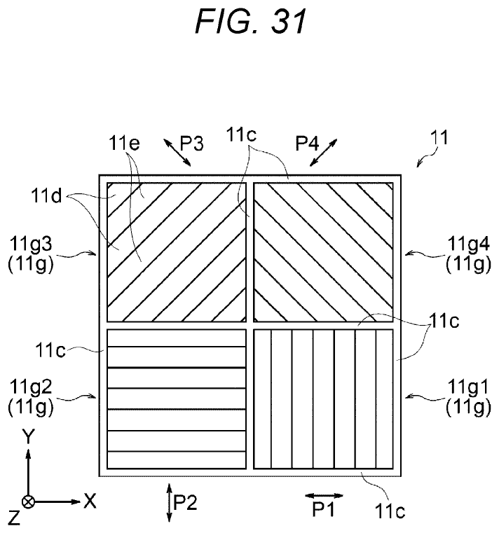

FIG. 28 is a plan view schematically illustrating the polarization controller 10 (in particular, polarization control unit) according to a second example of the second embodiment. FIG. 29 is a plan view schematically illustrating the additional polarizer 11 (in particular, additional polarization pixel unit) according to the second example of the second embodiment. FIG. 30 is a plan view schematically illustrating the polarization controller 10 (in particular, polarization control unit) according to a third example of the second embodiment. FIG. 31 is a plan view schematically illustrating the additional polarizer 11 (in particular, additional polarization pixel unit) according to the third example of the second embodiment.

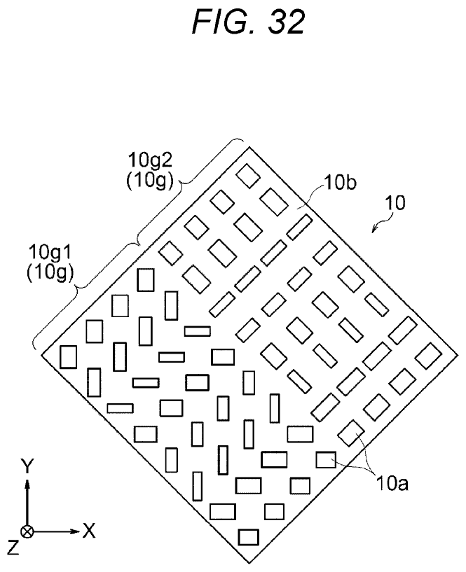

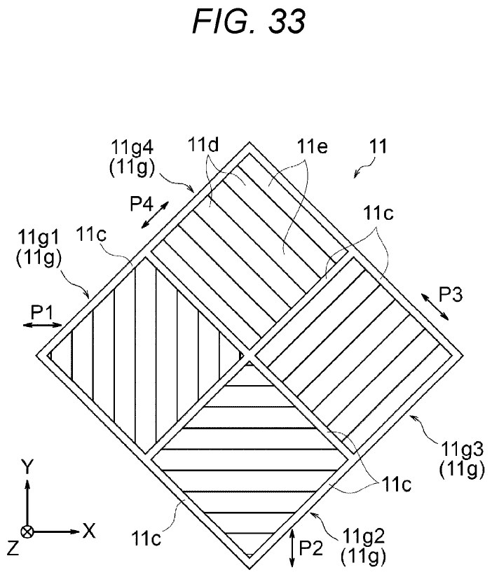

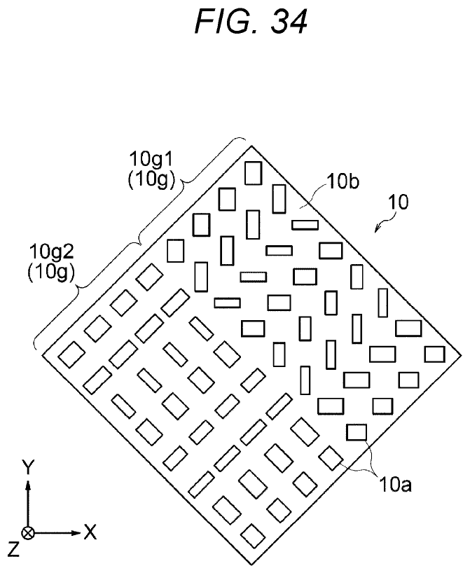

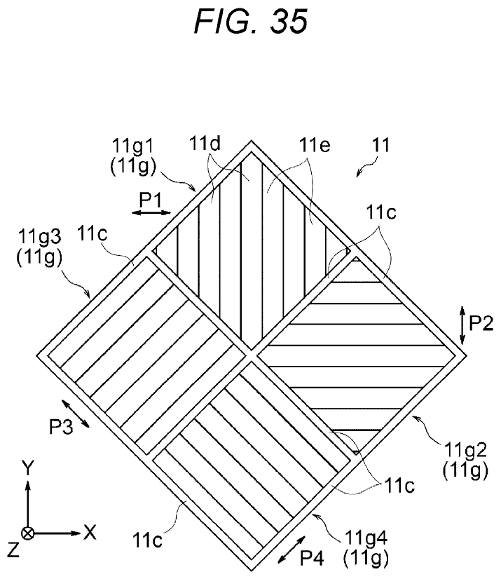

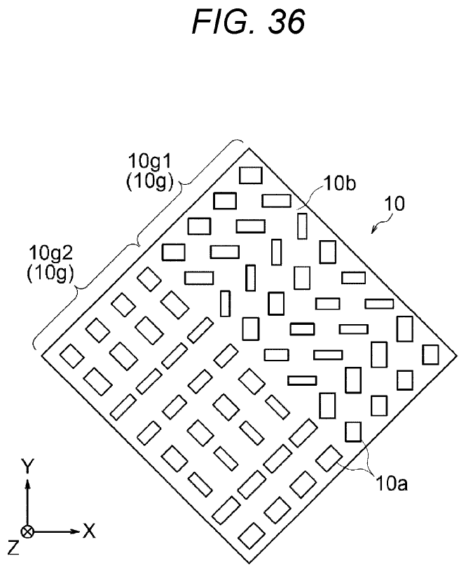

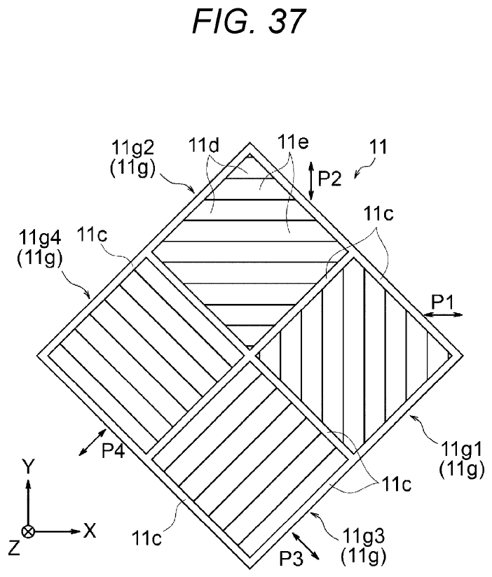

FIG. 32 is a plan view schematically illustrating the polarization controller 10 (in particular, polarization control unit) according to a fourth example of the second embodiment. FIG. 33 is a plan view schematically illustrating the additional polarizer 11 (in particular, additional polarization pixel unit) according to the fourth example of the second embodiment. FIG. 34 is a plan view schematically illustrating the polarization controller 10 (in particular, polarization control unit) according to a fifth example of the second embodiment. FIG. 35 is a plan view schematically illustrating the additional polarizer 11 (in particular, additional polarization pixel unit) according to the fifth example of the second embodiment. FIG. 36 is a plan view schematically illustrating the polarization controller 10 (in particular, polarization control unit) according to a sixth example of the second embodiment. FIG. 37 is a plan view schematically illustrating the additional polarizer 11 (in particular, additional polarization pixel unit) according to the sixth example of the second embodiment.

In the first to sixth examples (FIGS. 23 to 37) of the second embodiment, in a similar manner to the first to sixth examples of the first embodiment described above, the relative arrangements between the first light receiving pixel PX1 to fourth light receiving pixel PX4 that receive the first polarized light Lp1 to fourth polarized light Lp4 are different from each other.

That is, the first light receiving pixel PX1 to fourth light receiving pixel PX4 according to the first to sixth examples of the second embodiment are arranged in a similar manner to the first light receiving pixel PX1 to fourth light receiving pixel PX4 according to the respective first to sixth examples of the first embodiment described above. Furthermore, the first unit polarization control unit 10g1 and the second unit polarization control unit 10g2 according to the first to sixth examples of the second embodiment are arranged in a similar manner to the respective first to sixth examples of the first embodiment (see FIGS. 25, 28, 30, 32, 34, and 36). Furthermore, the first to fourth additional polarization pixels 11g1 to 11g4 according to the first to sixth examples of the second embodiment are arranged in a similar manner to the first to fourth additional polarization pixels 11g1 to 11g4 according to the respective first to sixth examples of the first embodiment (see FIGS. 26, 29, 31, 33, 35, and 37).

Note that, as illustrated in FIG. 9 described above, the additional polarizer 11 according to each of the examples of the present embodiment may include the additional polarization light shielding section 11c so that a substantial light receiving area of each additional polarization pixel 11g is limited and a distance between the light receiving areas of the adjacent additional polarization pixels 11g is increased.

### First Variation

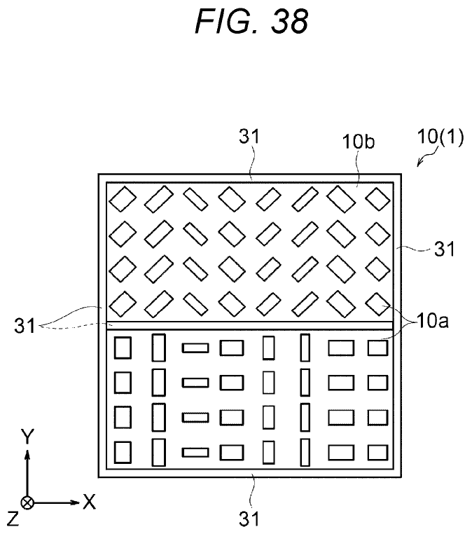

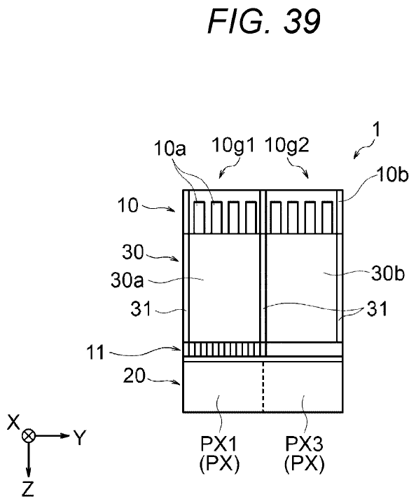

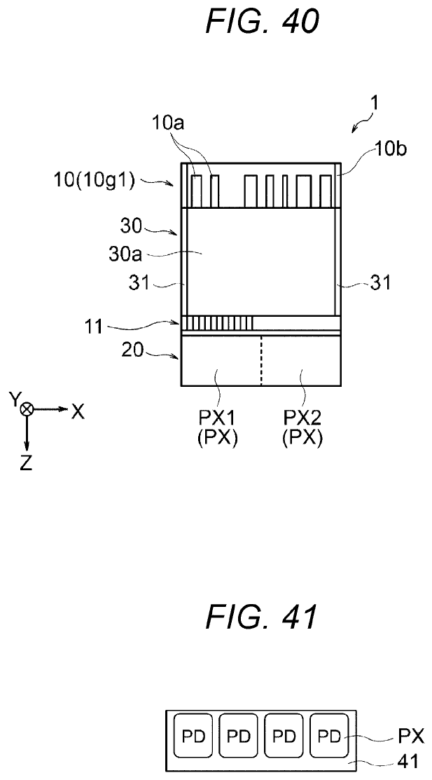

FIG. 38 is a plan view of a polarization controller 10 illustrating a first variation of an image sensor 1. FIG. 39 is a cross-sectional view illustrating an exemplary YZ plane of the image sensor 1 illustrated in FIG. 38. FIG. 40 is a cross-sectional view illustrating an exemplary XZ plane of the image sensor 1 illustrated in FIG. 38.

A waveguide path 30 provided between the polarization controller 10 and an additional polarizer 11 includes a first unit polarization waveguide 30a and a second unit polarization waveguide 30b. A polarization control light shielding section 31 is provided between the first unit polarization waveguide 30a and the second unit polarization waveguide 30b adjacent to each other. In the examples illustrated in FIGS. 38 to 40, the polarization control light shielding section 31 extends in a Z direction in the waveguide path 30, and also extends in the Z direction to penetrate the polarization controller 10 (in particular, portion including a boundary between a first unit polarization control unit 10g1 and a second unit polarization control unit 10g2).

The first unit polarization waveguide 30a is a region through which first polarized light Lp1 and second polarized light Lp2 emitted from the first unit polarization control unit 10g1 travel toward the additional polarizer 11 (in particular, first additional polarization pixel 11g1 and second additional polarization pixel 11g2). The second unit polarization waveguide 30b is a region through which third polarized light Lp3 and fourth polarized light Lp4 emitted from the second unit polarization control unit 10g2 travel toward the additional polarizer 11 (in particular, third additional polarization pixel 11g3 and fourth additional polarization pixel 11g4).

The polarization control light shielding section 31 has any configuration and any composition capable of shielding transmission of light (in particular, polarized light), and may be configured to shield light by reflecting the light, or may be configured to shield light by absorbing the light. As an example, the polarization control light shielding section 31 may include a member (e.g., plate-like metal (aluminum, etc.)) exhibiting high reflection performance with respect to light (in particular, polarized light). Furthermore, the polarization control light shielding section 31 may include a layer (e.g., low refractive index layer such as an air layer) having a composition with a refractive index different from that of the waveguide path 30 (first unit polarization waveguide 30a and second unit polarization waveguide 30b).

The first polarized light Lp1 and the second polarized light Lp2 in incident light L incident on the first unit polarization control unit 10g1 of the polarization controller 10 are made incident on the first additional polarization pixel 11g1 and the second additional polarization pixel 11g2, respectively, through the common first unit polarization waveguide 30a. Meanwhile, the third polarized light Lp3 and the fourth polarized light Lp4 in the incident light L incident on the second unit polarization control unit 10g2 of the polarization controller 10 are made incident on the third additional polarization pixel 11g3 and the fourth additional polarization pixel 11g4, respectively, through the common second unit polarization waveguide 30b.

The polarization control light shielding section 31 optically separates the first unit polarization waveguide 30a through which the first polarized light Lp1 and the second polarized light Lp2 pass and the second unit polarization waveguide 30b through which the third polarized light Lp3 and the fourth polarized light Lp4 pass. With this arrangement, crosstalk between the “first polarized light Lp1 and the second polarized light Lp2” and the “third polarized light Lp3 and the fourth polarized light Lp4” may be suppressed without interfering with a “split between the first polarized light Lp1 and the second polarized light Lp2” and a “split between the third polarized light Lp3 and the fourth polarized light Lp4”. As a result, an extinction ratio of the image sensor 1 may be improved.

Note that, while the polarization control light shielding section 31 is provided not only in the waveguide path 30 but also in the polarization controller 10 in the examples illustrated in FIGS. 38 to 40, the polarization control light shielding section 31 may be provided only in the waveguide path 30, and the polarization control light shielding section 31 may not be provided in the polarization controller 10.

### Manufacturing Method

Next, an example of a method of manufacturing the image sensor 1 will be described.

FIGS. 41 to 48 are cross-sectional views for explaining an example of the method of manufacturing the image sensor 1 (in particular, image sensor 1 including a wire grid additional polarizer 11).

First, as illustrated in FIG. 41, a substrate 41 having photodiodes PD constituting a light receiving pixel PX is prepared.

The photodiode PD may be formed on the substrate 41 by any method. As an example, doping of ion-implanting an n-type dopant into the substrate 41 including p-type Si may be performed, and activation by high-temperature annealing may be performed, whereby the photodiode PD may be formed for each pixel.

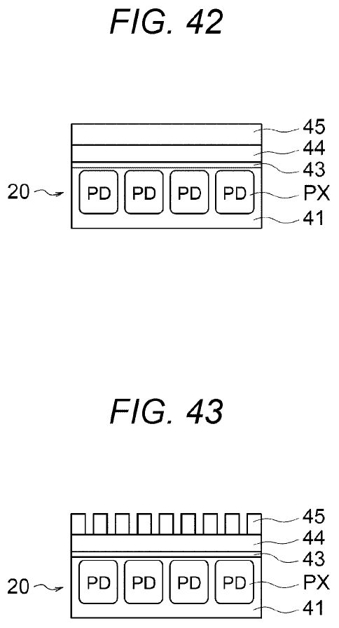

Thereafter, as illustrated in FIG. 42, an anti-reflection (AR) film 43, a silicon dioxide film 44, and an aluminum film 45 are sequentially formed and laminated on the substrate 41 to cover the photodiode PD. The anti-reflection film 43, the silicon dioxide film 44, and the aluminum film 45 may be laminated on the substrate 41 by any method (e.g., chemical vapor deposition (CVD) method).

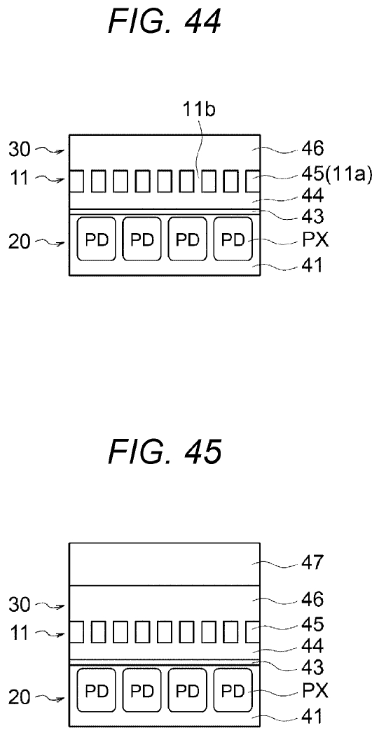

Thereafter, as illustrated in FIGS. 43 and 44, the aluminum film 45 is processed to form the additional polarizer 11 as a wire grid polarizer.

The aluminum film 45 may be processed into the wire grid polarizer by any method. As an example, fine grooves (through holes) are formed in the aluminum film 45 by dry etching (e.g., reactive ion etching (RIE)) using a photoresist based on lithography technology (see FIG. 43). Thereafter, a silicon dioxide film 46 is formed and laminated on the aluminum film 45 by any method (e.g., CVD method), whereby the fine grooves of the aluminum film 45 are filled with silicon dioxide (see FIG. 44).

As a result, the additional polarizer 11 having a wire 11a including aluminum and an inter-wire portion 11b including silicon dioxide is formed. In addition, the waveguide path 30 is configured by the silicon dioxide film 46 on the aluminum film 45.

Thereafter, as illustrated in FIGS. 45 to 47, the polarization controller 10 is formed on the silicon dioxide film 46 (waveguide path 30).

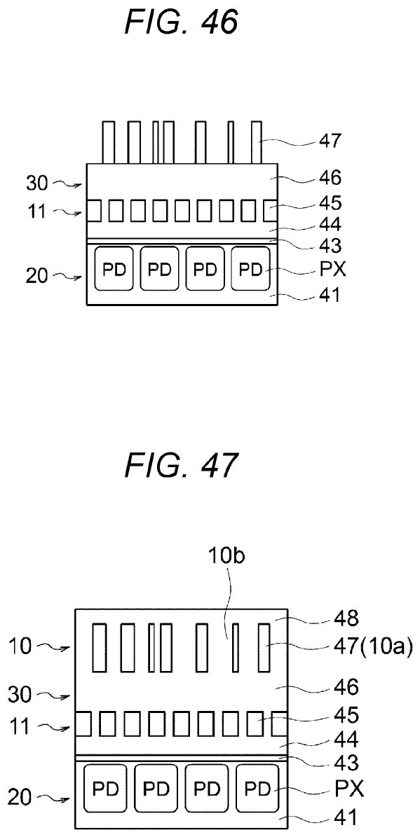

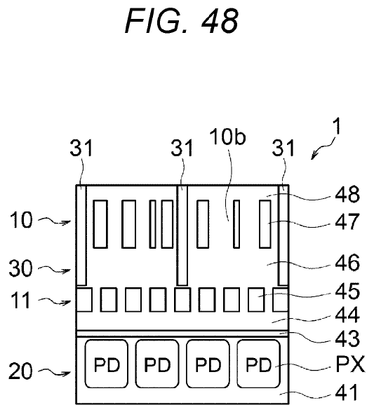

That is, as illustrated in FIG. 45, an amorphous silicon film 47 is formed and laminated on the silicon dioxide film 46 by any method (e.g., CVD method). Then, as illustrated in FIG. 46, fine grooves (through holes) are formed in the amorphous silicon film 47 by any method (e.g., dry etching such as RIE). Then, as illustrated in FIG. 47, a silicon dioxide film 48 is formed and laminated on the amorphous silicon film 47 by any method (e.g., CVD method), whereby the fine grooves of the amorphous silicon film 47 are filled with silicon dioxide.

As a result, the polarization controller 10 having a meta-surface structure including a meta-atom 10a including amorphous silicon and a structure peripheral portion 10b including silicon dioxide is formed.

Thereafter, as illustrated in FIG. 48, a hole (space) is formed in the silicon dioxide film 48, the silicon dioxide (structure peripheral portion 10b) filled in the fine grooves of the amorphous silicon film 47, and the silicon dioxide film 46. The hole may be formed by an any method (e.g., dry etching such as RIE), and constitutes the polarization control light shielding section 31 (air layer).

The image sensor 1 may be mass-produced by the series of processing described above (FIGS. 41 to 48) being performed.

As described above, according to each embodiment and each variation described above, the polarization controller 10 with the meta-surface structure having a polarization splitter function is arranged as an upper layer of the additional polarizer 11 having a polarization filter function.

With this arrangement, incidence of non-allocated undesired polarized light may be effectively suppressed while intensively allowing allocated desired polarized light to be incident on each light receiving pixel PX of a photoelectric conversion unit 20. As a result, the image sensor 1 (photodetection device) that exhibits high sensitivity to the four types of polarized light (first polarized light Lp1 to fourth polarized light Lp4) having different oscillation directions and has a favorable extinction ratio may be provided. A shape and the like of a subject may be highly accurately grasped on the basis of a detection result (including polarization information) of such an image sensor 1.

### Industrial Application Field

The technology of the present disclosure may be applied to various electronic devices, and may be used in the field of optoelectronics in general (including the field related to image sensors).

Typically, the image sensor 1 according to each embodiment and each variation described above may be used as an imaging instrument included in a camera system. Furthermore, the image sensor 1 according to each embodiment and each variation described above may be applied to a photodetection device other than the imaging instrument, and various electronic devices including such a photodetection device may be provided.

Such various electronic devices are capable of deriving the shape of the subject on the basis of the detection result (including polarization information) of the photodetection device (image sensor 1) and particularly useful in a situation where higher sensitivity and extinction ratio are required, and may highly accurately detect a movement and shape of the subject at high speed.

Thus, the photodetection device and the electronic device according to the present disclosure may recognize a gesture indicated by a human on the basis of the detection result (including polarization information), and may also detect a line-of-sight (eye movement, etc.) of a user by being configured as, for example, a head-mounted display. Accordingly, the photodetection device and the electronic device according to the present disclosure may be applied to game applications as an example, and may also be applied to virtual reality (VR) technology and augmented reality (AR) technology.

Furthermore, since the photodetection device and the electronic device according to the present disclosure are capable of high-speed detection of the subject shape based on the detection result (including polarization information), they may also be applied to a camera for industrial machines, and may be applied to, for example, manufacturing equipment such as a product assembly system using a robot.

It should be noted that the embodiments and variations disclosed in the present specification are illustrative only in all respects, and are not to be construed as limiting. The embodiments and variations described above may be omitted, replaced, or changed in various forms without departing from the scope and spirit of the appended claims. For example, the embodiments and variations described above may be combined in whole or in part, and other embodiments other than those described above may be combined with the embodiments or variations described above. Furthermore, the effects of the present disclosure described herein are merely examples, and other effects may be exerted.

A technical category embodying the technical idea described above is not limited. For example, the technical idea described above may be embodied by a computer program for causing a computer to execute one or a plurality of procedures (steps) included in the method of manufacturing or using the devices described above. Furthermore, the technical idea described above may be embodied by a computer-readable non-transitory recording medium in which such a computer program is recorded.

### APPENDIX

The technology of the present disclosure may also have the following configurations.

### Item 1

A photodetection device including:
a polarization controller that includes a plurality of two-dimensionally arrayed microstructures and selectively transmits a plurality of types of polarized light in incident light;
an additional polarizer, on which the plurality of types of polarized light from the polarization controller is made incident, that selectively transmits the plurality of types of polarized light; and
a photoelectric conversion unit including a plurality of light receiving pixels that receives the plurality of types of polarized light from the additional polarizer, in which
the plurality of types of polarized light transmitted through each of the polarization controller and the additional polarizer includes first polarized light, second polarized light, third polarized light, and fourth polarized light having mutually different oscillation directions.

### Item 2

The photodetection device according to Item 1, in which the polarization controller condenses the plurality of respective types of polarized light toward mutually different regions of the additional polarizer.

### Item 3

The photodetection device according to Item 1 or 2, in which
the additional polarizer includes a wire grid polarizer.

### Item 4

The photodetection device according to Item 1 or 2, in which
the additional polarizer includes a photonic crystal polarizer.

### Item 5

The photodetection device according to any one of Items 1 to 4, in which
the additional polarizer includes a plurality of additional polarization pixels and an additional polarization light shielding section provided between the additional polarization pixels adjacent to each other, and
each of the plurality of additional polarization pixels selectively transmits any one of the first polarized light, the second polarized light, the third polarized light, or the fourth polarized light.

### Item 6

The photodetection device according to any one of Items 1 to 5, in which
the first polarized light and the second polarized light have the oscillation directions different from each other by 90 degrees,
the third polarized light and the fourth polarized light have the oscillation directions different from each other by 90 degrees, and
the second polarized light and the third polarized light have the oscillation directions different from each other by 45 degrees.

### Item 7

The photodetection device according to any one of Items 1 to 6, in which
the polarization controller includes:
a first unit polarization control unit that selectively transmits the first polarized light and the second polarized light; and
a second unit polarization control unit that selectively transmits the third polarized light and the fourth polarized light,
the additional polarizer includes a plurality of additional polarization pixels that selectively transmits any one of the first polarized light, the second polarized light, the third polarized light, or the fourth polarized light,
the first unit polarization control unit is configured to:
condense the first polarized light toward the additional polarization pixel that selectively transmits the first polarized light; and
condense the second polarized light toward the additional polarization pixel that selectively transmits the second polarized light, and
the second unit polarization control unit is configured to:
condense the third polarized light toward the additional polarization pixel that selectively transmits the third polarized light; and
condense the fourth polarized light toward the additional polarization pixel that selectively transmits the fourth polarized light.

### Item 8

The photodetection device according to Item 7, further including:
a waveguide path provided between the polarization controller and the additional polarizer, in which
the waveguide path includes:
a first unit polarization waveguide through which the first polarized light and the second polarized light emitted from the first unit polarization control unit travel toward the additional polarizer; and
a second unit polarization waveguide through which the third polarized light and the fourth polarized light emitted from the second unit polarization control unit travel toward the additional polarizer, and
a polarization control light shielding section is provided between the first unit polarization waveguide and the second unit polarization waveguide adjacent to each other.

### Item 9

The photodetection device according to Item 8, in which
the polarization control light shielding section includes metal.

### Item 10

The photodetection device according to Item 8, in which
the polarization control light shielding section includes an air layer.

### Item 11

The photodetection device according to any one of Items 1 to 10, in which
the plurality of light receiving pixels has an oblique lattice array.

### Item 12

The photodetection device according to any one of Items 1 to 11, in which
the additional polarizer includes a plurality of additional polarization pixels having an oblique lattice array.

### Item 13

The photodetection device according to any one of Items 1 to 12, in which
the polarization controller includes a plurality of unit polarization control units having an oblique lattice array.

### Item 14

An electronic device including:
a photodetection device including:
a polarization controller that includes a plurality of two-dimensionally arrayed microstructures and selectively transmits a plurality of types of polarized light in incident light;
an additional polarizer, on which the plurality of types of polarized light from the polarization controller is made incident, that selectively transmits the plurality of types of polarized light; and
a photoelectric conversion unit including a plurality of light receiving pixels that receives the plurality of types of polarized light from the additional polarizer, in which
the plurality of types of polarized light transmitted through each of the polarization controller and the additional polarizer includes first polarized light, second polarized light, third polarized light, and fourth polarized light having mutually different oscillation directions.

### Item 15

The electronic device according to Item 14, in which the polarization controller condenses the plurality of respective types of polarized light toward mutually different regions of the additional polarizer.

### Item 16

The electronic device according to Item 14 or 15, in which
the additional polarizer includes a wire grid polarizer.

### Item 17

The electronic device according to Item 14 or 15, in which
the additional polarizer includes a photonic crystal polarizer.

### Item 18

The electronic device according to any one of Items 14 to 17, in which
the additional polarizer includes a plurality of additional polarization pixels and an additional polarization light shielding section provided between the additional polarization pixels adjacent to each other, and
each of the plurality of additional polarization pixels selectively transmits any one of the first polarized light, the second polarized light, the third polarized light, or the fourth polarized light.

### Item 19

The electronic device according to any one of Items 14 to 18, in which
the first polarized light and the second polarized light have the oscillation directions different from each other by 90 degrees,
the third polarized light and the fourth polarized light have the oscillation directions different from each other by 90 degrees, and
the second polarized light and the third polarized light have the oscillation directions different from each other by 45 degrees.

### Item 20

The electronic device according to any one of Items 14 to 19, in which
the polarization controller includes:
a first unit polarization control unit that selectively transmits the first polarized light and the second polarized light; and
a second unit polarization control unit that selectively transmits the third polarized light and the fourth polarized light,
the additional polarizer includes a plurality of additional polarization pixels that selectively transmits any one of the first polarized light, the second polarized light, the third polarized light, or the fourth polarized light,
the first unit polarization control unit is configured to:
condense the first polarized light toward the additional polarization pixel that selectively transmits the first polarized light; and
condense the second polarized light toward the additional polarization pixel that selectively transmits the second polarized light, and
the second unit polarization control unit is configured to:
condense the third polarized light toward the additional polarization pixel that selectively transmits the third polarized light; and
condense the fourth polarized light toward the additional polarization pixel that selectively transmits the fourth polarized light.

### Item 21

The electronic device according to Item 20, further including:
a waveguide path provided between the polarization controller and the additional polarizer, in which
the waveguide path includes:
a first unit polarization waveguide through which the first polarized light and the second polarized light emitted from the first unit polarization control unit travel toward the additional polarizer; and
a second unit polarization waveguide through which the third polarized light and the fourth polarized light emitted from the second unit polarization control unit travel toward the additional polarizer, and
a polarization control light shielding section is provided between the first unit polarization waveguide and the second unit polarization waveguide adjacent to each other.

### Item 22

The electronic device according to Item 21, in which
the polarization control light shielding section includes metal.

### Item 23

The electronic device according to Item 21, in which
the polarization control light shielding section includes an air layer.

### Item 24

The electronic device according to any one of Items 14 to 23, in which
the plurality of light receiving pixels has an oblique lattice array.

### Item 25

The electronic device according to any one of Items 14 to 24, in which
the additional polarizer includes a plurality of additional polarization pixels having an oblique lattice array.

### Item 26

The electronic device according to any one of Items 14 to 25, in which
the polarization controller includes a plurality of unit polarization control units having an oblique lattice array.

### REFERENCE SIGNS LIST

1 Image sensor
10 Polarization controller
10a Meta-atom
10b Structure peripheral portion
10g Unit polarization control unit
10g1 First unit polarization control unit
10g2 Second unit polarization control unit
11 Additional polarizer
11a Wire
11b Inter-wire portion
11c Additional polarization light shielding section
11d Low refractive index material
11e High refractive index material
11g Additional polarization pixel
11g1 First additional polarization pixel
11g2 Second additional polarization pixel
11g3 Third additional polarization pixel
11g4 Fourth additional polarization pixel
20 Photoelectric conversion unit
30 Waveguide path
30a First unit polarization waveguide
30b Second unit polarization waveguide
31 Polarization control light shielding section
41 Substrate
43 Anti-reflection film
44 Silicon dioxide film
45 Aluminum film
46 Silicon dioxide film
47 Amorphous silicon film
48 Silicon dioxide film
d Light receiving pixel size
L Incident light
Lp1 First polarized light
Lp2 Second polarized light
Lp3 Third polarized light
Lp4 Fourth polarized light
PD Photodiode
PX Light receiving pixel
PXg Light receiving pixel unit
PXn Specific light receiving pixel
PX1 First light receiving pixel
PX2 Second light receiving pixel
PX3 Third light receiving pixel
PX4 Fourth light receiving pixel
Tx X-direction periodic distance
Ty Y-direction periodic distance

1. A photodetection device comprising:
a polarization controller that includes a plurality of two-dimensionally arrayed microstructures and selectively transmits a plurality of types of polarized light in incident light;
an additional polarizer, on which the plurality of types of polarized light from the polarization controller is made incident, that selectively transmits the plurality of types of polarized light; and
a photoelectric conversion unit including a plurality of light receiving pixels that receives the plurality of types of polarized light from the additional polarizer, wherein
the plurality of types of polarized light transmitted through each of the polarization controller and the additional polarizer includes first polarized light, second polarized light, third polarized light, and fourth polarized light having mutually different oscillation directions.

2. The photodetection device according to claim 1, wherein the polarization controller condenses the plurality of respective types of polarized light toward mutually different regions of the additional polarizer.

3. The photodetection device according to claim 1, wherein
the additional polarizer includes a wire grid polarizer.

4. The photodetection device according to claim 1, wherein
the additional polarizer includes a photonic crystal polarizer.

5. The photodetection device according to claim 1, wherein
the additional polarizer includes a plurality of additional polarization pixels and an additional polarization light shielding section provided between the additional polarization pixels adjacent to each other, and
each of the plurality of additional polarization pixels selectively transmits any one of the first polarized light, the second polarized light, the third polarized light, or the fourth polarized light.

6. The photodetection device according to claim 1, wherein
the first polarized light and the second polarized light have the oscillation directions different from each other by 90 degrees,
the third polarized light and the fourth polarized light have the oscillation directions different from each other by 90 degrees, and
the second polarized light and the third polarized light have the oscillation directions different from each other by 45 degrees.

7. The photodetection device according to claim 1, wherein
the polarization controller includes:
a first unit polarization control unit that selectively transmits the first polarized light and the second polarized light; and
a second unit polarization control unit that selectively transmits the third polarized light and the fourth polarized light,
the additional polarizer includes a plurality of additional polarization pixels that selectively transmits any one of the first polarized light, the second polarized light, the third polarized light, or the fourth polarized light,
the first unit polarization control unit is configured to:
condense the first polarized light toward the additional polarization pixel that selectively transmits the first polarized light; and
condense the second polarized light toward the additional polarization pixel that selectively transmits the second polarized light, and
the second unit polarization control unit is configured to:
condense the third polarized light toward the additional polarization pixel that selectively transmits the third polarized light; and
condense the fourth polarized light toward the additional polarization pixel that selectively transmits the fourth polarized light.

8. The photodetection device according to claim 7, further comprising:
a waveguide path provided between the polarization controller and the additional polarizer, wherein
the waveguide path includes:
a first unit polarization waveguide through which the first polarized light and the second polarized light emitted from the first unit polarization control unit travel toward the additional polarizer; and
a second unit polarization waveguide through which the third polarized light and the fourth polarized light emitted from the second unit polarization control unit travel toward the additional polarizer, and
a polarization control light shielding section is provided between the first unit polarization waveguide and the second unit polarization waveguide adjacent to each other.

9. The photodetection device according to claim 8, wherein
the polarization control light shielding section includes metal.

10. The photodetection device according to claim 8, wherein
the polarization control light shielding section includes an air layer.

11. The photodetection device according to claim 1, wherein
the plurality of light receiving pixels has an oblique lattice array.

12. The photodetection device according to claim 1, wherein
the additional polarizer includes a plurality of additional polarization pixels having an oblique lattice array.

13. The photodetection device according to claim 1, wherein
the polarization controller includes a plurality of unit polarization control units having an oblique lattice array.

14. An electronic device comprising:
a photodetection device including:
a polarization controller that includes a plurality of two-dimensionally arrayed microstructures and selectively transmits a plurality of types of polarized light in incident light;
an additional polarizer, on which the plurality of types of polarized light from the polarization controller is made incident, that selectively transmits the plurality of types of polarized light; and
a photoelectric conversion unit including a plurality of light receiving pixels that receives the plurality of types of polarized light from the additional polarizer, in which
the plurality of types of polarized light transmitted through each of the polarization controller and the additional polarizer includes first polarized light, second polarized light, third polarized light, and fourth polarized light having mutually different oscillation directions.
